(19) United States
(12) Patent Application Publication
(10) Pub. No.: US 2023/0217816 A1
(43) Pub. Date: Jul. 6, 2023

(54) LIGHT EMITTING DEVICE AND LIGHT EMITTING DISPLAY DEVICE INCLUDING THE SAME

(71) Applicant: LG Display Co., Ltd., Seoul (KR)

(72) Inventors: Wook SONG, Paju-si (KR); Myeong Seon CHO, Paju-si (KR); Sae Mi PARK, Paju-si (KR); Jung Keun KIM, Paju-si (KR); Do Han KIM, Paju-si (KR); Byung Soo KIM, Paju-si (KR); Hye Seung KANG, Paju-si (KR)

(73) Assignee: LG Display Co., Ltd., Seoul (KR)

(21) Appl. No.: 18/084,235

(22) Filed: Dec. 19, 2022

(30) Foreign Application Priority Data
Dec. 31, 2021 (KR) 10-2021-0194798

(51) Int. Cl. H10K 85/60; H10K 50/13

(52) U.S. Cl. CPC H01L 51/0067; H01L 51/0072; H01L 51/0073; H01L 51/0074; H01L 51/504; H01L 51/5012

(57) ABSTRACT

Disclosed is a light emitting device capable of improving color purity and luminance, reducing a material driving voltage, and exhibiting a longer lifespan by changing the configuration of a green stack. The light emitting device includes a first electrode and a second electrode facing each other, and a light emitting unit including a p-type charge generation layer, a hole transport layer, and a green light emitting layer, which are sequentially stacked, wherein the green light emitting layer includes a triazine-based compound as a host and a phosphorescent dopant.

### CROSS-REFERENCE TO RELATED APPLICATION

This application claims the benefit of and priority to Korean Patent Application No. 10-2021-0194798, filed on Dec. 31, 2021, which is hereby incorporated by reference as if fully set forth herein.

### BACKGROUND

### Technical Field

The present disclosure relates to a light emitting device, and more particularly to a light emitting device that is capable of improving efficiency of emission of white light, securing the stability over time and thus prolonging the lifespan by improving the exciton efficiency for each color equally in the phosphorescent stack based on the change of the materials of the hole transport layer and the green light emitting layer of the phosphorescent stack adjacent to the blue stack, and a light emitting display device including the same.

### Description of the Related Art

Recently, a light emitting display device that does not require a separate light source and has a light emitting device in a display panel without a separate light source to make the display device compact and realize clear color has been considered a competitive application.

Meanwhile, light emitting devices currently used in light emitting display devices require higher efficiency in order to realize desired image quality, and are preferably implemented in the form of a plurality of stacks.

In addition, in response to the demand for higher image quality, a display device requires high color purity. For this purpose, research is being conducted on improving color purity and improving luminance of all colors by providing a single light emitting layer for each stack.

However, when a single light emitting layer is provided for each stack in order to improve color purity, there is a problem in that the driving voltage is increased due to the large number of stacks.

### SUMMARY OF THE DISCLOSURE

Accordingly, one or more embodiments of the present disclosure are directed to a light emitting device and a light emitting display device including the same that substantially obviate one or more problems due to the limitations and disadvantages of the related art.

It is an object of the present disclosure to provide a light emitting device that is capable of securing high efficiency and a longer lifespan without increasing the driving voltage even in a structure having multiple stacks including a single light emitting layer for each stack in order to increase color purity, and a light emitting display device including the same.

Additional features and aspects will be set forth in the description that follows, and in part will be apparent from the description, or may be learned by practice of the present disclosure concepts provided herein. Other features and aspects of the present disclosure concepts may be realized and attained by the structure particularly pointed out in the written description, or derivable therefrom, and the claims hereof as well as the appended drawings.

The light emitting device of the present disclosure is capable of improving color purity and luminance, reducing a material driving voltage, and exhibiting a longer lifespan by changing the configuration in the green stack.

To achieve these and other advantages and in accordance with objects of the disclosure, as described herein, an aspect of the present disclosure is a light emitting device includes a first electrode and a second electrode facing each other and a light emitting unit including a p-type charge generation layer, a hole transport layer, and a green light emitting layer that are sequentially stacked, wherein the green light emitting layer includes a triazine-based compound as a host, and a phosphorescent dopant.

In another aspect of the present disclosure, a light emitting display device includes a substrate including a plurality of subpixels, a thin film transistor provided at each of the subpixels on the substrate, and the light emitting device connected to the thin film transistor.

It is to be understood that both the foregoing general description and the following detailed description of the present disclosure are merely by way of example and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure. In the drawings:

FIG. 1 is a cross-sectional view illustrating a light emitting device according to an embodiment of the present disclosure;

FIG. 2 is an energy band diagram for each layer of a green stack according to an embodiment of a light emitting device of the present disclosure;

FIG. 3 is a cross-sectional view illustrating light emitting devices used in first and second experimental example groups;

FIG. 4 is a graph showing the emission spectrum of the first experimental example group;

FIG. 5 is a graph showing the emission spectrum of the second experimental example group;

FIGS. 6A and 6B are diagrams showing the configuration of phosphorescent stacks according to third and fourth experimental examples;

FIG. 7 is a cross-sectional view illustrating light emitting devices according to fifth to seventh experimental examples of the present disclosure;

FIG. 8 is a graph showing white emission spectra of light emitting devices according to the fifth to seventh experimental examples of FIG. 7;

FIG. 9 is a cross-sectional view showing a light emitting device according to another embodiment of the present disclosure; and

FIG. 10 is a cross-sectional view illustrating a light emitting display device using the light emitting device of the present disclosure according to an exemplary embodiment.

### DETAILED DESCRIPTION

Reference will now be made in detail to some of the examples and embodiments of the disclosure illustrated in the accompanying drawings. Wherever possible, the same reference numbers will be used throughout the drawings to refer to the same or like parts. In the following description of the present disclosure, detailed descriptions of known functions and configurations incorporated herein will be omitted when the same may obscure the subject matter of the present disclosure. In addition, the names of elements used in the following description are selected in consideration of clarity of description of the specification, and may differ from the names of elements of actual products.

The shape, size, ratio, angle, number, and the like shown in the drawings to illustrate various embodiments of the present disclosure are merely provided for illustration, and the disclosure is not limited to the content shown in the drawings. Wherever possible, the same reference numbers will be used throughout the drawings to refer to the same or like parts. In the following description, detailed descriptions of technologies or configurations related to the present disclosure may be omitted so as to avoid unnecessarily obscuring the subject matter of the present disclosure. When terms such as “including”, “having”, and “comprising” are used throughout the specification, an additional component may be present, unless “only” is used. A component described in a singular form encompasses a plurality thereof unless particularly stated otherwise.

The components included in the embodiments of the present disclosure should be interpreted to include an error range, even if there is no additional particular description thereof.

In describing the variety of embodiments of the present disclosure, when terms describing positional relationships, such as “on”, “above”, “under”, and “next to”, are used, at least one intervening element may be present between the two elements, unless “immediately” or “directly” is also used.

In describing the variety of embodiments of the present disclosure, when terms related to temporal relationships, such as “after”, “subsequently”, “next”, and “before”, are used, the non-continuous case may be included, unless “immediately” or “directly” is also used.

In describing the variety of embodiments of the present disclosure, terms such as “first” and “second” may be used to describe a variety of components, but these terms only aim to distinguish the same or similar components from one another. Accordingly, throughout the specification, a “first” component may be the same as a “second” component within the technical concept of the present disclosure, unless specifically mentioned otherwise.

Features of various embodiments of the present disclosure may be partially or completely coupled to or combined with each other, and may be variously inter-operated with each other and driven technically. The embodiments of the present disclosure may be carried out independently from each other, or may be carried out together in an interrelated manner.

As used herein, the term “doped” means that, in a material that accounts for most of the weight of a layer, a material (for example, n-type and p-type materials, or organic and inorganic substances) having physical properties different from the material that occupies most of the weight ratio of the layer is added in an amount less than 30% by weight. In other words, a “doped” layer is a layer that is used to distinguish a host material from a dopant material of a certain layer, in consideration of the weight ratio. Also, the term “undoped” refers to any case other than the “doped” case. For example, when a layer contains a single material or a mixture of materials having the same properties as each other, the layer is included in the “undoped” layer. For example, if at least one of the materials constituting a certain layer is p-type and not all materials constituting the layer are n-type, the layer is included in the “undoped” layer. For example, if at least one of materials constituting a layer is an organic material and not all materials constituting the layer are inorganic materials, the layer is included in the “undoped” layer. For example, if all materials constituting a certain layer are organic materials, at least one of the materials constituting the layer is n-type and the other is p-type, when the n-type material is present in an amount of less than 30 wt%, or when the p-type material is present in an amount of less than 30 wt%, the layer is included in the “doped” layer.

Hereinafter, a light emitting device of the present disclosure and a light emitting display device including the same will be described with reference to the drawings.

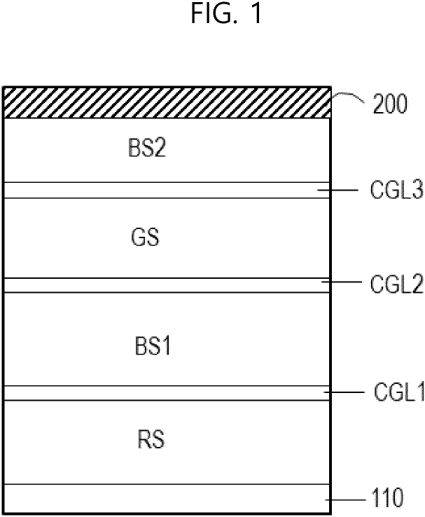

FIG. 1 is a cross-sectional view illustrating a light emitting device according to an embodiment of the present disclosure.

As shown in FIG. 1, the light emitting device according to the embodiment of the present disclosure includes a first electrode 110 and a second electrode 200 facing each other; a red stack RS, a first blue stack BS1, a green stack GS, and a second blue stack BS2 sequentially provided between the first electrode 110 and the second electrode 200; and charge generation layers CGL1, CGL2, and CGL3 provided between the respective stacks RS, BS1, GS, and BS2.

Here, the light emitting device according to FIG. 1 includes a single light emitting layer for each stack RS, BS1, GS, or BS2 in order to obtain high purity for each color to realize white color.

Here, each stack RS, BS1, GS, or BS2 includes a light emitting layer of each color, a hole transport layer disposed under the light emitting layer (close to the first electrode 110), and an electron transport layer disposed on the light emitting layer (close to the second electrode 200).

The first electrode 110 and the second electrode 200 are also referred to as an “anode” and a “cathode”, respectively. In some cases, inverse to the configuration shown in FIG. 1, an anode may be provided on an upper side, and a cathode may be provided on a lower side.

At least one of the first electrode 110 and the second electrode 200 may include a transparent electrode, and the other may include a reflective electrode, thereby determining the passage direction of light.

In some cases, one of the first electrode 110 and the second electrode 200 is a transparent electrode and the other is a thin reflective electrode, so the strong cavity of the first and second electrodes 110 and 200 can be maintained, light can be emitted within a range having a small half width from each light emitting layer and thus light efficiency can be improved.

FIG. 1 shows that each of a red stack RS and a green stack GS is provided singly and that a blue stack has a double stack configuration including first and second blue stacks BS1 and BS2. This aims to compensate for the fact that the efficiency of the blue stack including the fluorescent light emitting layer is lower than that of the red stack RS and the green stack GS including phosphorescent light emitting layers. In some cases, the number of blue stacks may be decreased or increased by changing the material of the blue light emitting layer.

Meanwhile, the positions of the red stack RS, the first blue stack BS1, the green stack GS, and the second blue stack BS2 shown in FIG. 1 may be changed as needed.

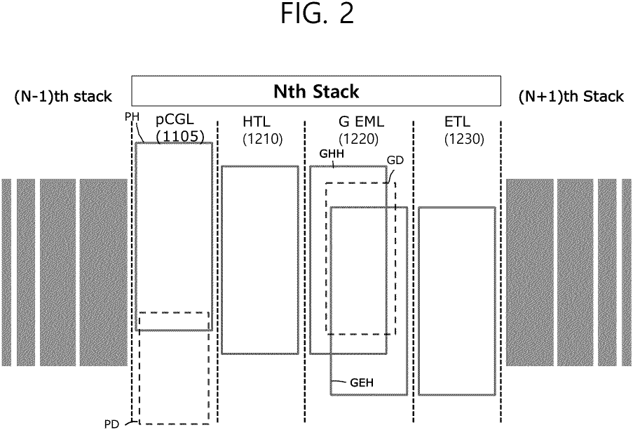

FIG. 2 is an energy band diagram for each layer of a green stack according to an embodiment of a light emitting device of the present disclosure.

In FIG. 2, N may be a natural number of 2 or more.

Accordingly, as the N^{th} stack, the green stack may be disposed as the second or next stack from the first electrode 110 and may be disposed between the first electrode 110 and a further next stack emitting light of a different color.

For example, FIG. 1 shows a configuration in which the green stack GS is provided between the first and second blue stacks BS1 and BS2, and satisfies the configuration of FIG. 2.

A light emitting unit including the green stack (N^{th} stack) provided in FIG. 2 may include a p-type charge generation layer (pCGL) 1105, a hole transport layer (HTL) 1210, a green light emitting layer (G EML) 1220, and an electron transport layer (ETL) 1230 which are stacked in that order.

That is, the light emitting unit including the green stack (N^{th} stack) of FIG. 2 includes the hole transport layer 1210 and the electron transport layer 1230, which are disposed on both sides of the green light emitting layer 1220, and is capable of confining holes and electrons in the green light emitting layer 1220 as a single phosphorescent light emitting layer without a separate control layer, thus emitting light with high external quantum efficiency in the green light emitting layer 1220. This is also possible by changing the material of the electron-transporting host GEH included in the green light emitting layer 1220 and the electron transport layer 1230.

The material of the hole transport layer and the known material for the host of the phosphorescent layer generally used in the phosphorescent stack are determined in consideration of exciton distribution in each of phosphorescent layers present in the phosphorescent stack. When the materials are used in the green phosphorescent light emitting layer, the position of the light emitting region is biased toward the interface with the hole transport layer or the electron transport layer, so it is difficult to obtain a high light-emission efficiency from a phosphorescent green light emitting layer.

In the light emitting unit shown in FIG. 2, the p-type charge generation layer 1105 is a layer that generates holes and supplies the holes to the green light emitting layer 1220 because the green stack is not directly adjacent to the first electrode (or anode). The p-type charge generation layer 1105 includes an amine-based compound as a host (PH) and an organic material including a fluorene-based compound in an amount of 0.1 wt% to 30 wt% as a p-type dopant (PD) to promote hole generation and hole transport.

The LUMO energy level of the p-type dopant PD is approximately similar to the HOMO energy level of the host PH in the p-type charge generation layer 1105.

In addition, the material of the hole transport layer (HTL) 1210 has a HOMO energy level of about -5.8 eV to about -5.4 eV, and a HOMO energy level lower than the HOMO energy level of the host material PH of the p-type charge generation layer (pCGL) 1105 to receive holes from the adjacent p-type charge generation layer (pCGL) 1105.

In addition, the green light emitting layer 1220 of the green stack in the light emitting device of the present disclosure includes an electron-transporting host (GEH), a hole-transporting host (GHH) and a green dopant (GD) doped in an amount of 1 wt% to 30 wt% in the hosts (GEH, GHH).

The hole-transporting host (GHH) has a HOMO energy level of about -6.1 eV to about -5.4 eV, and has a HOMO energy level equal to or lower than the HOMO energy level of the hole transport layer (HTL) 1210 to receive holes from the adjacent hole transport layer (HTL) 1210.

In addition, the electron-transporting host GEH functions to receive electrons and effectively transfer the electrons to the green dopant GD and the overall energy band gap of the electron-transporting host GEH is lower than that of the hole-transporting host GHH. Accordingly, the HOMO energy level of the electron-transporting host GEH is about -6.8 eV to about -5.6 eV.

In addition, the green dopant GD preferably has a HOMO energy level higher than the HOMO energy level of the hole-transporting host GHH to receive holes from the hole-transporting host GHH. The green dopant GD may have an emission peak at a wavelength of 510 nm to 550 nm, and may include a metal complex compound such as an iridium complex compound.

In the light emitting device of the present disclosure, the green light emitting layer 1220 has the maximum luminous efficiency based on a single element structure not in contact with light emitting layers of other colors. For this purpose, one side of the green light emitting layer 1220 contacts the hole transport layer 1210 and the other side thereof contacts the electron transport layer 1230.

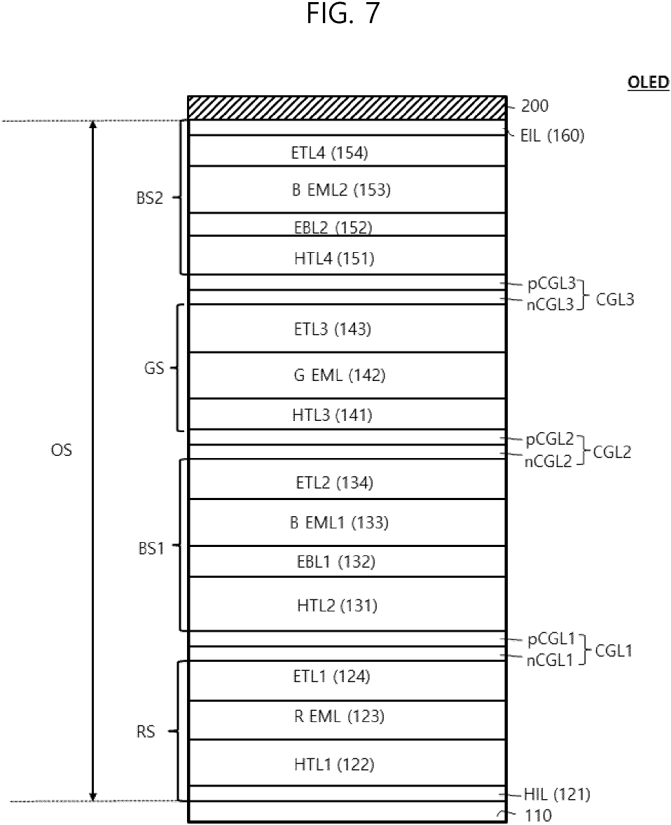

In addition, the other side of the electron transport layer 1230 that does not contact the green light emitting layer 1220 may contact the charge generation layer (nCGL) or the electron injection layer (see EIL of FIG. 7) of the charge generation layer (see CGL of FIG. 1) disposed between the electron transport layer 1230 and the next stack ((N+1)^{th} stack). The n-type charge generation layer (nCGL) may be an organic layer doped with a metal and the electron injection layer may be an inorganic material or an organic-inorganic compound having a metal compound such as LiF or Liq (lithium quinolate) .

In addition, the other side of the electron transport layer 1230, which is not in contact with the green light emitting layer, may be in contact with an organic layer doped with a metal or an inorganic layer having a metal compound.

At least one of the p-type charge generation layer and the n-type charge generation layer is adjacent to a blue stack (BS1 or BS2 in FIG. 1) including a blue light emitting layer, and the blue light emitting layer may include a blue dopant having an emission peak at a wavelength of 420 nm to 480 nm.

The electron-transporting host (GEH) of the green light emitting layer 1220 in the light emitting device of the present disclosure may include a triazine compound represented by the following Formula 1.

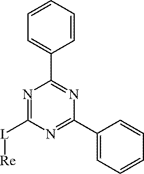

Re includes at least one of a dibenzofuran group, a dibenzothiophene group, a triphenyl group, a triphenylene group, a carbazole group, a benzocarbazole group, an indenocarbazole group, a biscarbazole group, a fluorene group and a phenyl-carbazole group. L is a single bond or includes at least one of a phenyl group, a phenylene group, a biphenyl group, a biphenylene group, a dibenzofuran group, a dibenzofurylene group, and dibenzothiophene group, and a dibenzothienylene group.

In one embodiment, L is a biphenyl group or a phenyl group and Re is an indenocarbazole (e.g. 7,7-Dimethyl-5,7-dihydroindeno[2,1-b]carbazole). In one embodiment, L is a single bond and Re are two phenyl-carbazoles.

In one embodiment, L is a dibenzofuran group or a dibenzothiophene group and Re is a phenyl-carbazole or a triphenylene group.

In addition, examples of the compounds of Formula 1 described above may include the compounds of TRZ-01 to TRZ-27.

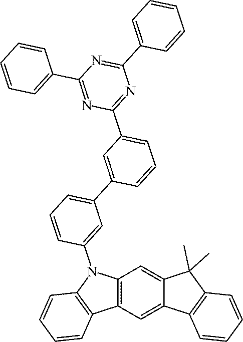 [SMILES: CC1(C)c2ccccc2-c2cc3c4ccccc4n(-c4cccc(-c5cccc(-c6nc(-c7ccccc7)nc(-c7ccccc7)n6)c5)c4)c3cc21]

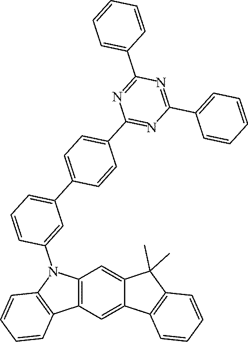 [SMILES: CC1(C)c2ccccc2-c2cc3c4ccccc4n(-c4cccc(-c5ccc(-c6nc(-c7ccccc7)nc(-c7ccccc7)n6)cc5)c4)c3cc21]

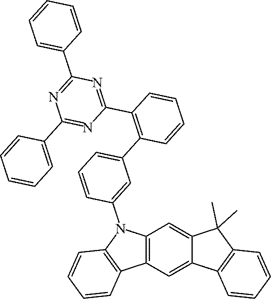 [SMILES: CC1(C)c2ccccc2-c2cc3c4ccccc4n(-c4cccc(-c5ccccc5-c5nc(-c6ccccc6)nc(-c6ccccc6)n5)c4)c3cc21]

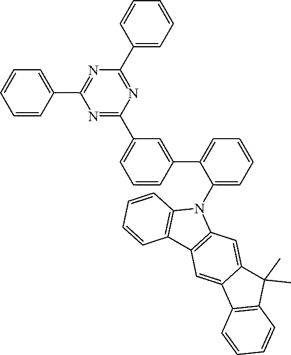 [SMILES: CC1(C)c2ccccc2-c2cc3c4ccccc4n(-c4ccccc4-c4cccc(-c5nc(-c6ccccc6)nc(-c6ccccc6)n5)c4)c3cc21]

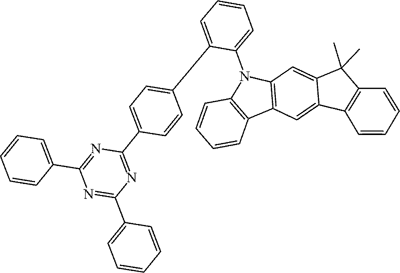 [SMILES: CC1(C)c2ccccc2-c2cc3c4ccccc4n(-c4ccccc4-c4ccc(-c5nc(-c6ccccc6)nc(-c6ccccc6)n5)cc4)c3cc21]

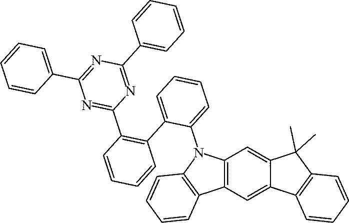 [SMILES: CC1(C)c2ccccc2-c2cc3c4ccccc4n(-c4ccccc4-c4ccccc4-c4nc(-c5ccccc5)nc(-c5ccccc5)n4)c3cc21]

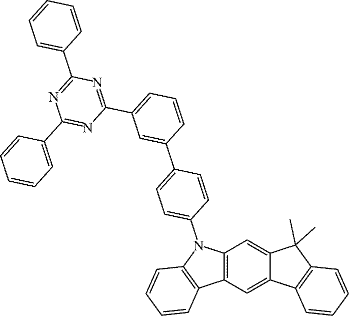 [SMILES: CC1(C)c2ccccc2-c2cc3c4ccccc4n(-c4ccc(-c5cccc(-c6nc(-c7ccccc7)nc(-c7ccccc7)n6)c5)cc4)c3cc21]

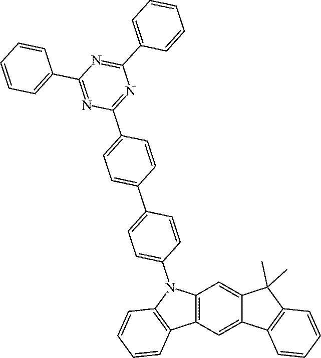 [SMILES: CC1(C)c2ccccc2-c2cc3c4ccccc4n(-c4ccc(-c5ccc(-c6nc(-c7ccccc7)nc(-c7ccccc7)n6)cc5)cc4)c3cc21]

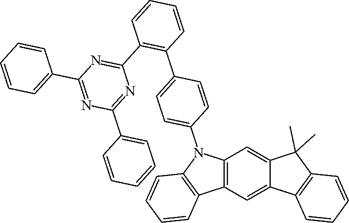 [SMILES: CC1(C)c2ccccc2-c2cc3c4ccccc4n(-c4ccc(-c5ccccc5-c5nc(-c6ccccc6)nc(-c6ccccc6)n5)cc4)c3cc21]

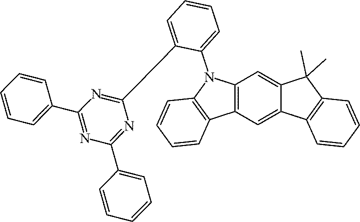 [SMILES: CC1(C)c2ccccc2-c2cc3c4ccccc4n(-c4ccccc4-c4nc(-c5ccccc5)nc(-c5ccccc5)n4)c3cc21]

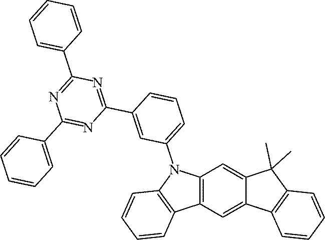 [SMILES: CC1(C)c2ccccc2-c2cc3c4ccccc4n(-c4cccc(-c5nc(-c6ccccc6)nc(-c6ccccc6)n5)c4)c3cc21]

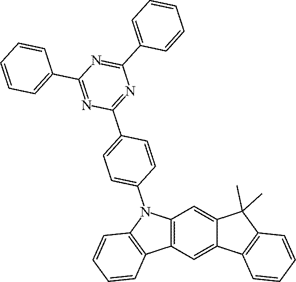 [SMILES: CC1(C)c2ccccc2-c2cc3c4ccccc4n(-c4ccc(-c5nc(-c6ccccc6)nc(-c6ccccc6)n5)cc4)c3cc21]

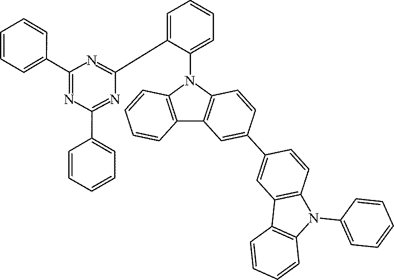 [SMILES: c1ccc(-c2nc(-c3ccccc3)nc(-c3ccccc3-n3c4ccccc4c4cc(-c5ccc6c(c5)c5ccccc5n6-c5ccccc5)ccc43)n2)cc1]

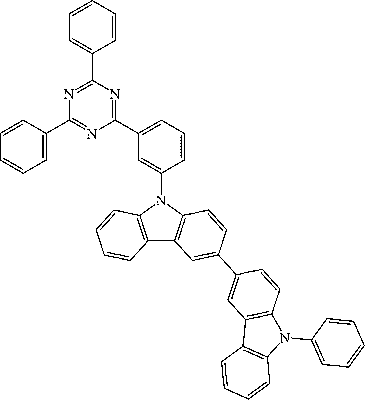 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

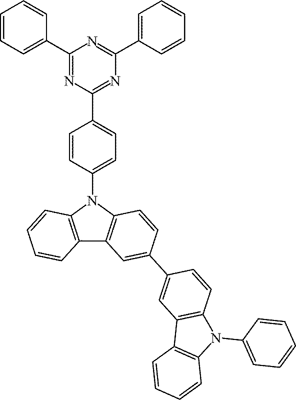 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

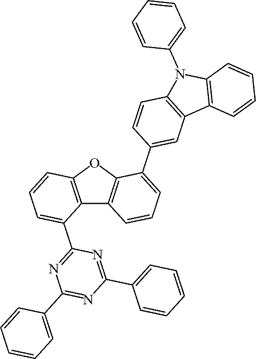 [SMILES: c1ccc(-c2nc(-c3ccccc3)nc(-c3cccc4oc5c(-c6ccc7c(c6)c6ccccc6n7-c6ccccc6)cccc5c34)n2)cc1]

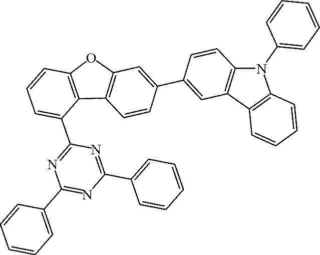 [SMILES: c1ccc(-c2nc(-c3ccccc3)nc(-c3cccc4oc5cc(-c6ccc7c(c6)c6ccccc6n7-c6ccccc6)ccc5c34)n2)cc1]

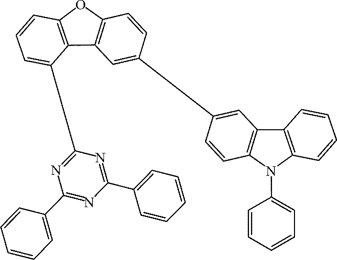 [SMILES: c1ccc(-c2nc(-c3ccccc3)nc(-c3cccc4oc5ccc(-c6ccc7c(c6)c6ccccc6n7-c6ccccc6)cc5c34)n2)cc1]

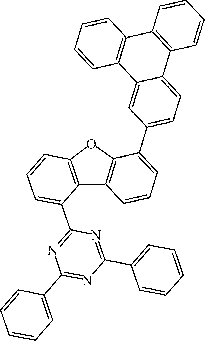 [SMILES: c1ccc(-c2nc(-c3ccccc3)nc(-c3cccc4oc5c(-c6ccc7c8ccccc8c8ccccc8c7c6)cccc5c34)n2)cc1]

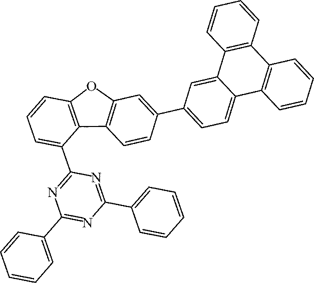 [SMILES: c1ccc(-c2nc(-c3ccccc3)nc(-c3cccc4oc5cc(-c6ccc7c8ccccc8c8ccccc8c7c6)ccc5c34)n2)cc1]

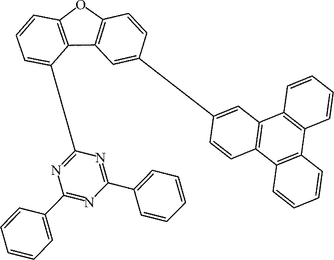 [SMILES: c1ccc(-c2nc(-c3ccccc3)nc(-c3cccc4oc5ccc(-c6ccc7c8ccccc8c8ccccc8c7c6)cc5c34)n2)cc1]

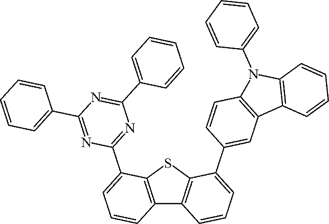 [SMILES: c1ccc(-c2nc(-c3ccccc3)nc(-c3cccc4c3sc3c(-c5ccc6c(c5)c5ccccc5n6-c5ccccc5)cccc34)n2)cc1]

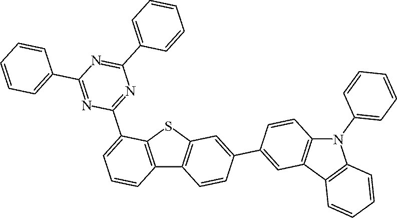 [SMILES: c1ccc(-c2nc(-c3ccccc3)nc(-c3cccc4c3sc3cc(-c5ccc6c(c5)c5ccccc5n6-c5ccccc5)ccc34)n2)cc1]

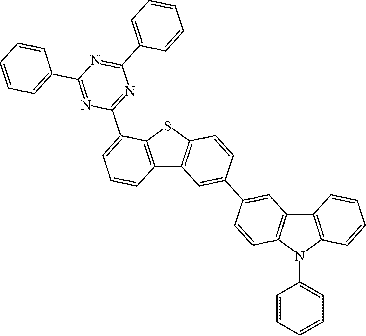 [SMILES: c1ccc(-c2nc(-c3ccccc3)nc(-c3cccc4c3sc3ccc(-c5ccc6c(c5)c5ccccc5n6-c5ccccc5)cc34)n2)cc1]

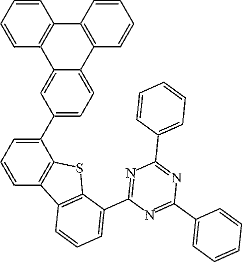 [SMILES: c1ccc(-c2nc(-c3ccccc3)nc(-c3cccc4c3sc3c(-c5ccc6c7ccccc7c7ccccc7c6c5)cccc34)n2)cc1]

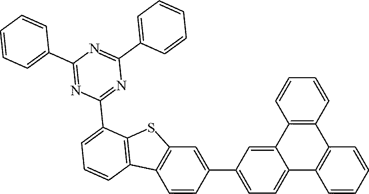 [SMILES: c1ccc(-c2nc(-c3ccccc3)nc(-c3cccc4c3sc3cc(-c5ccc6c7ccccc7c7ccccc7c6c5)ccc34)n2)cc1]

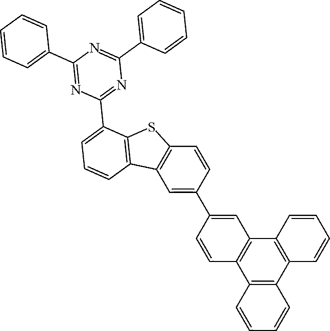 [SMILES: c1ccc(-c2nc(-c3ccccc3)nc(-c3cccc4c3sc3ccc(-c5ccc6c7ccccc7c7ccccc7c6c5)cc34)n2)cc1]

In addition, the hole transport layer 1210 in contact with the green light emitting layer (G EML) 1220 includes the following biscarbazole-based compound and thus is capable of effectively transporting holes while avoiding accumulation on the interface, without a separate control layer between the green light emitting layer 1220 and the hole transport layer 1210.

The biscarbazole-based compound contained in the hole transport layer 1210 may include a second material of Formula 2.

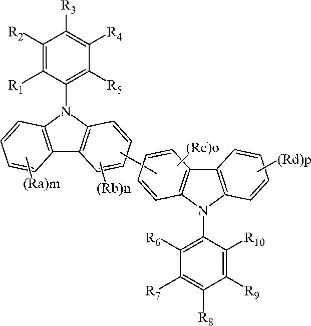

Ra to Rd are each independently selected from hydrogen, deuterium, halogen, a substituted or unsubstituted C1-C6 alkyl group, a substituted or unsubstituted C3-C6 cycloalkyl group, a substituted or unsubstituted C6-C15 aryl group, a substituted or unsubstituted C5-C9 heteroaryl group, a carbazole group, a dibenzofuran group, a dibenzothiophene group, a trialkylsilyl group, and a triarylsilyl group. m and p are each independently selected from integers from 0 to 4. n and o are each independently selected from integers from 0 to 3. R₁ to R₁₀ are each independently selected from hydrogen, deuterium, halogen, a substituted or unsubstituted C1-C6 alkyl group, a substituted or unsubstituted C6-C18 aryl group, a carbazole group, a phenyl-carbazole group, a dibenzofuran group, and a dibenzothiophene group; or two or more of R₁ to R₁₀ together with the phenyl group that they are connected with may form a condensed aryl group. Preferably, the C6-C18 aryl group may be a phenyl group, a biphenyl group, or a triphenylene group. Preferably, the condensed aryl groups may be a naphthyl group, a phenanthrene group, or a triphenylene group, Preferably, the C5-C9 heteroaryl group may contain one or more hetero atoms selected from oxygen, sulfur and nitrogen in its aryl ring structure.

In one embodiment, m, n, o, p are 0. In one embodiment, four of R₁ to R₅ are independently of each other hydrogen, deuterium or halogen and one of R₁ to R₅ is a phenyl group, a biphenyl group, a dibenzofuran group, a dibenzothiophene group, a carbazole group or a phenyl-carbazole group. In one embodiment, at least one of R₆ to R₁₀ are hydrogen, deuterium or halogen and at most four of R₆ to R₁₀ are independently of each other hydrogen, a phenyl group, a triphenylene group, a phenanthrene group, an anthracene group, a naphthyl group, or two or more of R₆ to R₁₀ together with the phenyl group that they are connected with may form a condensed aryl group, wherein the condensed aryl group is preferably a naphthyl group, a phenanthrene group, or a triphenylene group.

Moreover, examples of such a biscarbazole-based compound include the following materials BCA-01 to BCA-44.

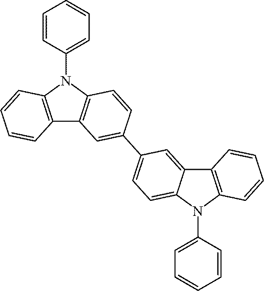 [SMILES: c1ccc(-n2c3ccccc3c3cc(-c4ccc5c(c4)c4ccccc4n5-c4ccccc4)ccc32)cc1]

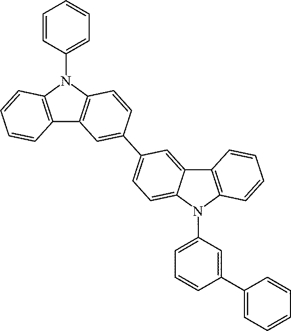 [SMILES: c1ccc(-c2cccc(-n3c4ccccc4c4cc(-c5ccc6c(c5)c5ccccc5n6-c5ccccc5)ccc43)c2)cc1]

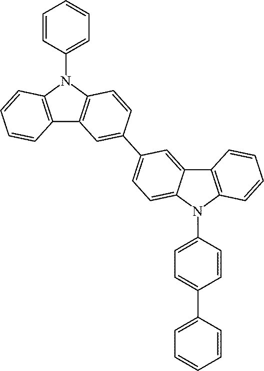 [SMILES: c1ccc(-c2ccc(-n3c4ccccc4c4cc(-c5ccc6c(c5)c5ccccc5n6-c5ccccc5)ccc43)cc2)cc1]

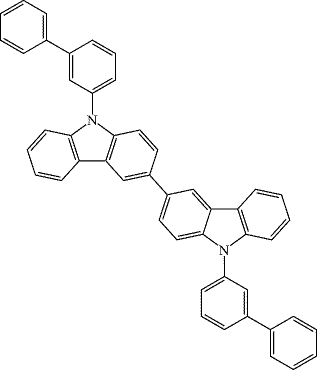 [SMILES: c1ccc(-c2cccc(-n3c4ccccc4c4cc(-c5ccc6c(c5)c5ccccc5n6-c5cccc(-c6ccccc6)c5)ccc43)c2)cc1]

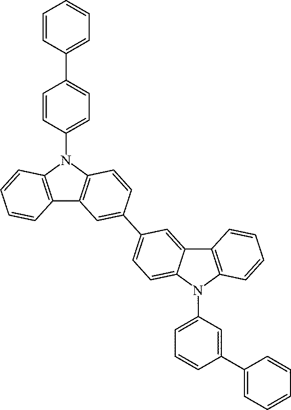 [SMILES: c1ccc(-c2ccc(-n3c4ccccc4c4cc(-c5ccc6c(c5)c5ccccc5n6-c5cccc(-c6ccccc6)c5)ccc43)cc2)cc1]

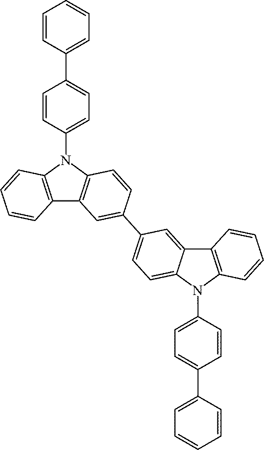 [SMILES: c1ccc(-c2ccc(-n3c4ccccc4c4cc(-c5ccc6c(c5)c5ccccc5n6-c5ccc(-c6ccccc6)cc5)ccc43)cc2)cc1]

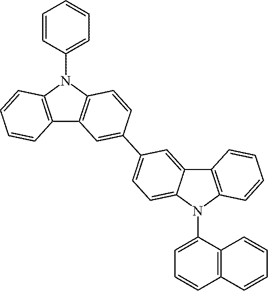 [SMILES: c1ccc(-n2c3ccccc3c3cc(-c4ccc5c(c4)c4ccccc4n5-c4cccc5ccccc45)ccc32)cc1]

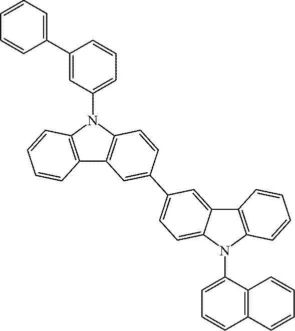 [SMILES: c1ccc(-c2cccc(-n3c4ccccc4c4cc(-c5ccc6c(c5)c5ccccc5n6-c5cccc6ccccc56)ccc43)c2)cc1]

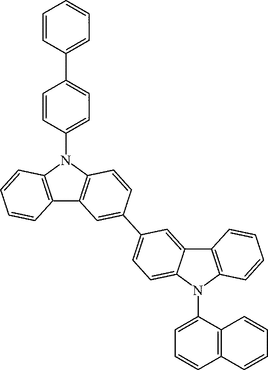 [SMILES: c1ccc(-c2ccc(-n3c4ccccc4c4cc(-c5ccc6c(c5)c5ccccc5n6-c5cccc6ccccc56)ccc43)cc2)cc1]

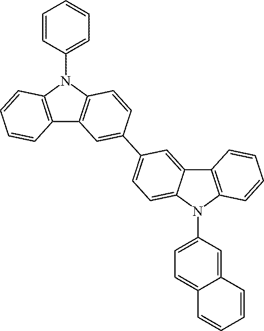 [SMILES: c1ccc(-n2c3ccccc3c3cc(-c4ccc5c(c4)c4ccccc4n5-c4ccc5ccccc5c4)ccc32)cc1]

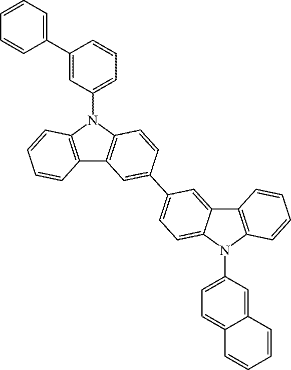 [SMILES: c1ccc(-c2cccc(-n3c4ccccc4c4cc(-c5ccc6c(c5)c5ccccc5n6-c5ccc6ccccc6c5)ccc43)c2)cc1]

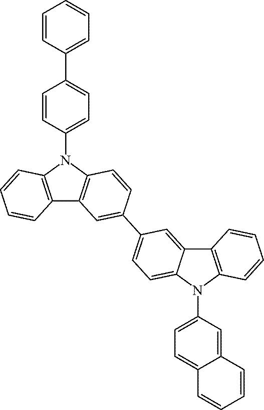 [SMILES: c1ccc(-c2ccc(-n3c4ccccc4c4cc(-c5ccc6c(c5)c5ccccc5n6-c5ccc6ccccc6c5)ccc43)cc2)cc1]

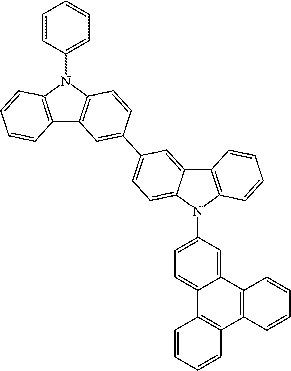 [SMILES: c1ccc(-n2c3ccccc3c3cc(-c4ccc5c(c4)c4ccccc4n5-c4ccc5c6ccccc6c6ccccc6c5c4)ccc32)cc1]

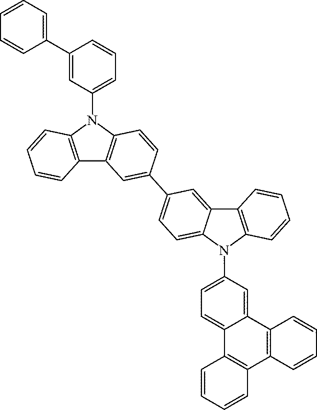 [SMILES: c1ccc(-c2cccc(-n3c4ccccc4c4cc(-c5ccc6c(c5)c5ccccc5n6-c5ccc6c7ccccc7c7ccccc7c6c5)ccc43)c2)cc1]

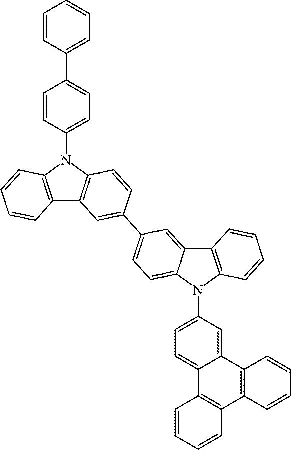 [SMILES: c1ccc(-c2ccc(-n3c4ccccc4c4cc(-c5ccc6c(c5)c5ccccc5n6-c5ccc6c7ccccc7c7ccccc7c6c5)ccc43)cc2)cc1]

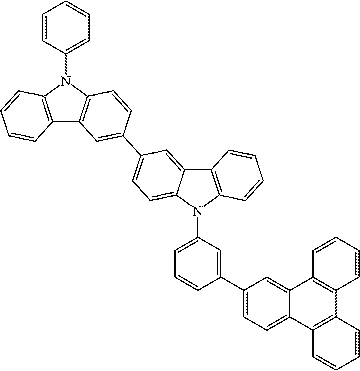 [SMILES: c1ccc(-n2c3ccccc3c3cc(-c4ccc5c(c4)c4ccccc4n5-c4cccc(-c5ccc6c7ccccc7c7ccccc7c6c5)c4)ccc32)cc1]

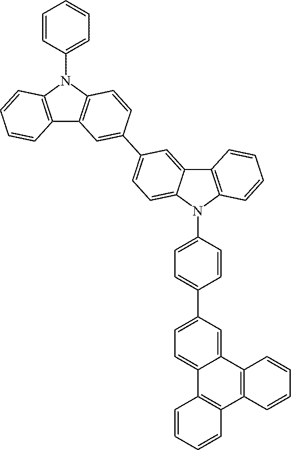 [SMILES: c1ccc(-n2c3ccccc3c3cc(-c4ccc5c(c4)c4ccccc4n5-c4ccc(-c5ccc6c7ccccc7c7ccccc7c6c5)cc4)ccc32)cc1]

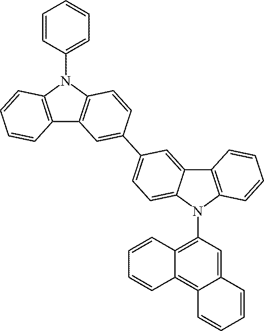 [SMILES: c1ccc(-n2c3ccccc3c3cc(-c4ccc5c(c4)c4ccccc4n5-c4cc5ccccc5c5ccccc45)ccc32)cc1]

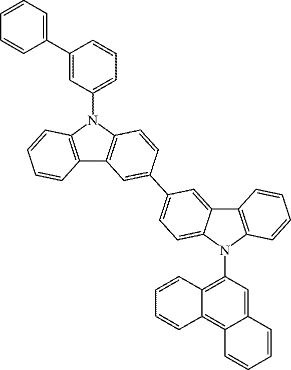 [SMILES: c1ccc(-c2cccc(-n3c4ccccc4c4cc(-c5ccc6c(c5)c5ccccc5n6-c5cc6ccccc6c6ccccc56)ccc43)c2)cc1]

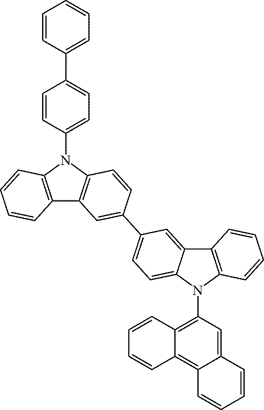 [SMILES: c1ccc(-c2ccc(-n3c4ccccc4c4cc(-c5ccc6c(c5)c5ccccc5n6-c5cc6ccccc6c6ccccc56)ccc43)cc2)cc1]

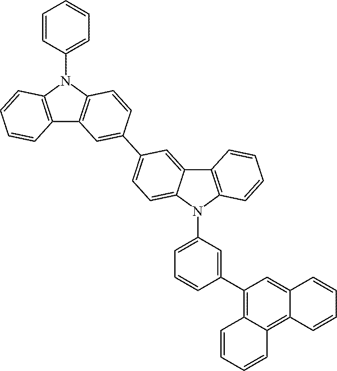 [SMILES: c1ccc(-n2c3ccccc3c3cc(-c4ccc5c(c4)c4ccccc4n5-c4cccc(-c5cc6ccccc6c6ccccc56)c4)ccc32)cc1]

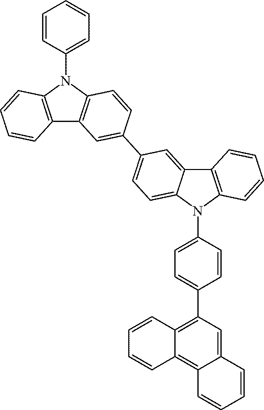 [SMILES: c1ccc(-n2c3ccccc3c3cc(-c4ccc5c(c4)c4ccccc4n5-c4ccc(-c5cc6ccccc6c6ccccc56)cc4)ccc32)cc1]

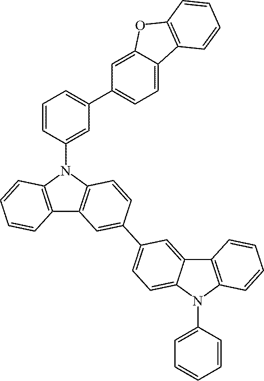 [SMILES: c1ccc(-n2c3ccccc3c3cc(-c4ccc5c(c4)c4ccccc4n5-c4cccc(-c5ccc6c(c5)oc5ccccc56)c4)ccc32)cc1]

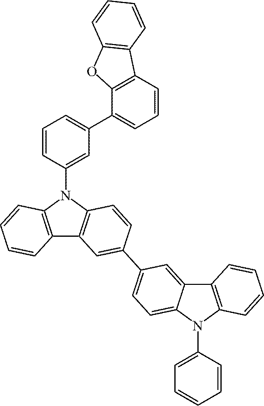 [SMILES: c1ccc(-n2c3ccccc3c3cc(-c4ccc5c(c4)c4ccccc4n5-c4cccc(-c5cccc6c5oc5ccccc56)c4)ccc32)cc1]

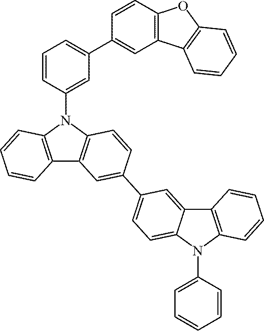 [SMILES: c1ccc(-n2c3ccccc3c3cc(-c4ccc5c(c4)c4ccccc4n5-c4cccc(-c5ccc6oc7ccccc7c6c5)c4)ccc32)cc1]

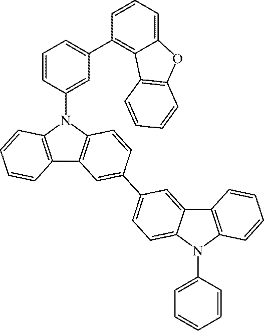 [SMILES: c1ccc(-n2c3ccccc3c3cc(-c4ccc5c(c4)c4ccccc4n5-c4cccc(-c5cccc6oc7ccccc7c56)c4)ccc32)cc1]

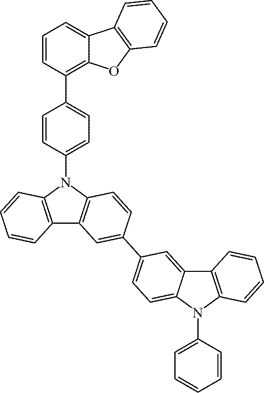 [SMILES: c1ccc(-n2c3ccccc3c3cc(-c4ccc5c(c4)c4ccccc4n5-c4ccc(-c5cccc6c5oc5ccccc56)cc4)ccc32)cc1]

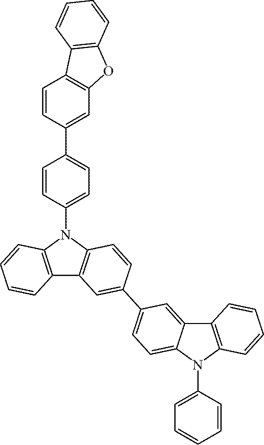 [SMILES: c1ccc(-n2c3ccccc3c3cc(-c4ccc5c(c4)c4ccccc4n5-c4ccc(-c5ccc6c(c5)oc5ccccc56)cc4)ccc32)cc1]

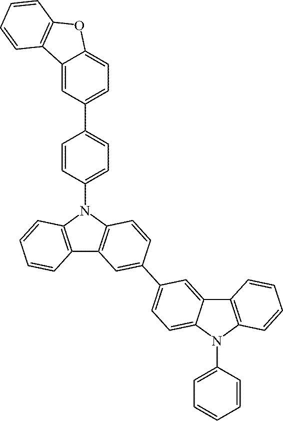 [SMILES: c1ccc(-n2c3ccccc3c3cc(-c4ccc5c(c4)c4ccccc4n5-c4ccc(-c5ccc6oc7ccccc7c6c5)cc4)ccc32)cc1]

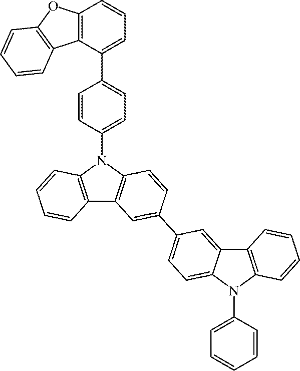 [SMILES: c1ccc(-n2c3ccccc3c3cc(-c4ccc5c(c4)c4ccccc4n5-c4ccc(-c5cccc6oc7ccccc7c56)cc4)ccc32)cc1]

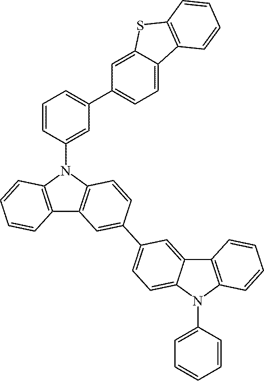 [SMILES: c1ccc(-n2c3ccccc3c3cc(-c4ccc5c(c4)c4ccccc4n5-c4cccc(-c5ccc6c(c5)sc5ccccc56)c4)ccc32)cc1]

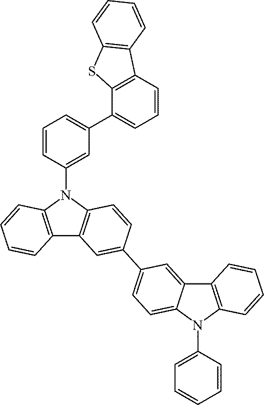 [SMILES: c1ccc(-n2c3ccccc3c3cc(-c4ccc5c(c4)c4ccccc4n5-c4cccc(-c5cccc6c5sc5ccccc56)c4)ccc32)cc1]

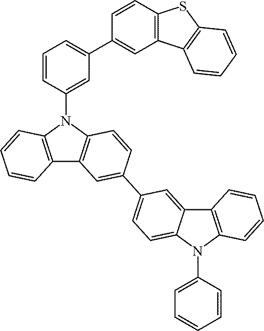 [SMILES: c1ccc(-n2c3ccccc3c3cc(-c4ccc5c(c4)c4ccccc4n5-c4cccc(-c5ccc6sc7ccccc7c6c5)c4)ccc32)cc1]

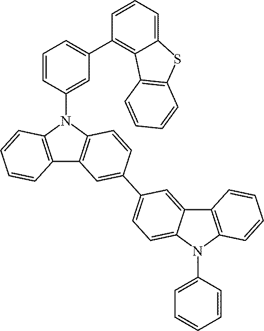 [SMILES: c1ccc(-n2c3ccccc3c3cc(-c4ccc5c(c4)c4ccccc4n5-c4cccc(-c5cccc6sc7ccccc7c56)c4)ccc32)cc1]

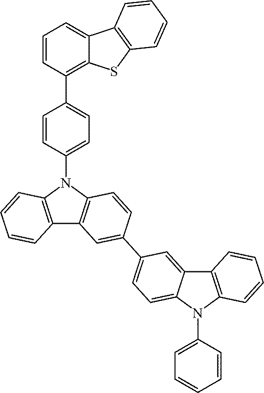 [SMILES: c1ccc(-n2c3ccccc3c3cc(-c4ccc5c(c4)c4ccccc4n5-c4ccc(-c5cccc6c5sc5ccccc56)cc4)ccc32)cc1]

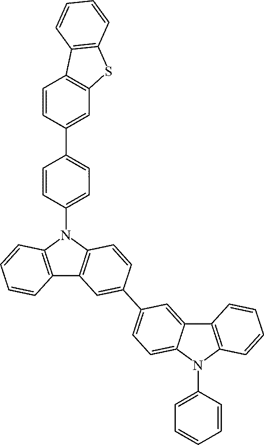 [SMILES: c1ccc(-n2c3ccccc3c3cc(-c4ccc5c(c4)c4ccccc4n5-c4ccc(-c5ccc6c(c5)sc5ccccc56)cc4)ccc32)cc1]

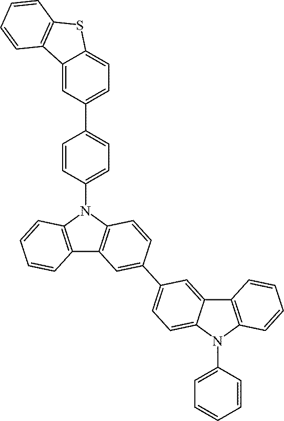 [SMILES: c1ccc(-n2c3ccccc3c3cc(-c4ccc5c(c4)c4ccccc4n5-c4ccc(-c5ccc6sc7ccccc7c6c5)cc4)ccc32)cc1]

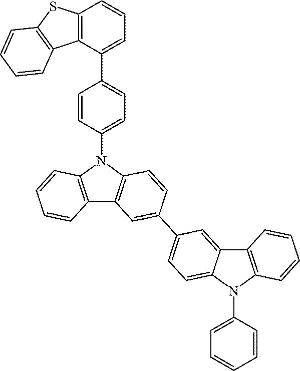 [SMILES: c1ccc(-n2c3ccccc3c3cc(-c4ccc5c(c4)c4ccccc4n5-c4ccc(-c5cccc6sc7ccccc7c56)cc4)ccc32)cc1]

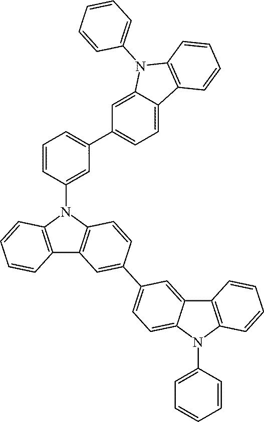 [SMILES: c1ccc(-n2c3ccccc3c3cc(-c4ccc5c(c4)c4ccccc4n5-c4cccc(-c5ccc6c7ccccc7n(-c7ccccc7)c6c5)c4)ccc32)cc1]

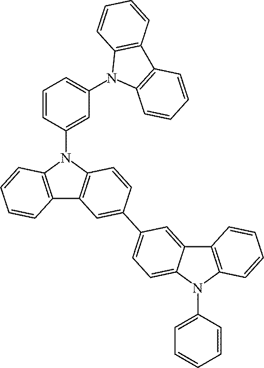 [SMILES: c1ccc(-n2c3ccccc3c3cc(-c4ccc5c(c4)c4ccccc4n5-c4cccc(-n5c6ccccc6c6ccccc65)c4)ccc32)cc1]

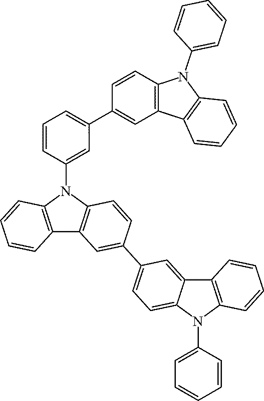 [SMILES: c1ccc(-n2c3ccccc3c3cc(-c4cccc(-n5c6ccccc6c6cc(-c7ccc8c(c7)c7ccccc7n8-c7ccccc7)ccc65)c4)ccc32)cc1]

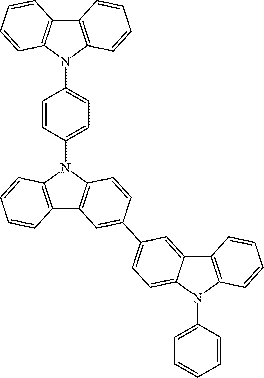 [SMILES: c1ccc(-n2c3ccccc3c3cc(-c4ccc5c(c4)c4ccccc4n5-c4ccc(-n5c6ccccc6c6ccccc65)cc4)ccc32)cc1]

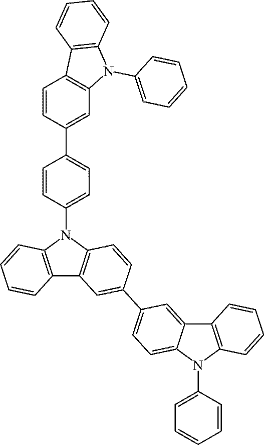 [SMILES: c1ccc(-n2c3ccccc3c3cc(-c4ccc5c(c4)c4ccccc4n5-c4ccc(-c5ccc6c7ccccc7n(-c7ccccc7)c6c5)cc4)ccc32)cc1]

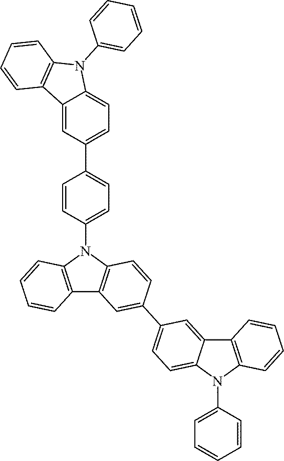 [SMILES: c1ccc(-n2c3ccccc3c3cc(-c4ccc(-n5c6ccccc6c6cc(-c7ccc8c(c7)c7ccccc7n8-c7ccccc7)ccc65)cc4)ccc32)cc1]

Hereinafter, the significance of each material will be determined by changing the materials of the hole-transporting host of the hole transport layer and the electron-transporting host of the adjacent phosphorescent green light emitting layer in the structure of a light emitting device having a phosphorescent green light emitting layer as a single stack.

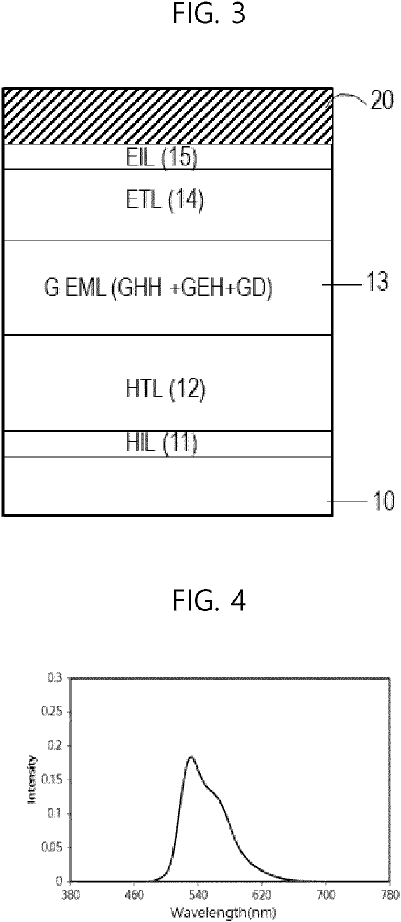

The light emitting devices of FIG. 3 according to the first experimental example group (Ex1-1 to Ex1-52) and the second experimental example group (Ex2-1 to Ex2-71) were formed and comparatively tested.

FIG. 3 is a cross-sectional view illustrating light emitting devices used in the first and second experimental example groups.

As shown in FIG. 3, the light emitting devices according to the first experimental example group (Ex1-1 to Ex1-52) are formed in accordance with the following process.

First, a first electrode 10 is formed using ITO.

Then, DNTPD and MgF₂ are co-deposited at a weight ratio of 1:1 to 7.5 nm to form a hole injection layer (HIL) 11.

Then, an amine-based material (HM-01 to HM-25) is deposited to a thickness of 15 nm to form a hole transport layer (HTL) 12.

Then, a green light emitting layer (G EML) 13 is formed to a thickness of 40 nm by doping a mixture of CBP as a hole-transporting host and a triazine-based compound as an electron-transporting host GEH at a weight ratio of 1:1 at 15 wt% with Ir(ppy)₃.

Then, TPBI is deposited to a thickness of 25 nm to form an electron transport layer (ETL) 14.

Then, LiF is deposited to a thickness of 2 nm to form an electron injection layer (EIL) 15 and then a second electrode 20 is formed using aluminum (Al).

In the experiments of the first experimental example group (Ex1-1 to Ex1-52), the material of the hole transport layer 12 is an amine-based compound and the electron-transporting host of the green phosphorescent layer is a triazine-based compound represented by Formula 1.

The amine-based compound used in the first experimental example group (Ex1-1 to Ex1-52) may be selected from the following compounds of HM-01 to HM-25.

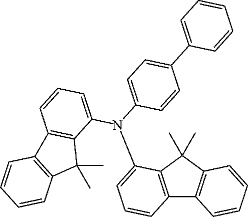 [SMILES: CC1(C)c2ccccc2-c2cccc(N(c3ccc(-c4ccccc4)cc3)c3cccc4c3C(C)(C)c3ccccc3-4)c21]

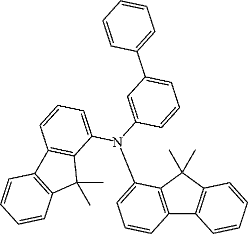 [SMILES: CC1(C)c2ccccc2-c2cccc(N(c3cccc(-c4ccccc4)c3)c3cccc4c3C(C)(C)c3ccccc3-4)c21]

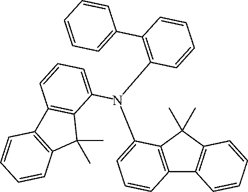 [SMILES: CC1(C)c2ccccc2-c2cccc(N(c3ccccc3-c3ccccc3)c3cccc4c3C(C)(C)c3ccccc3-4)c21]

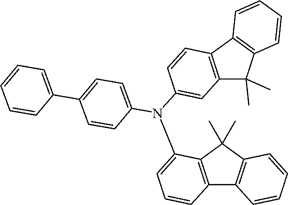 [SMILES: CC1(C)c2ccccc2-c2ccc(N(c3ccc(-c4ccccc4)cc3)c3cccc4c3C(C)(C)c3ccccc3-4)cc21]

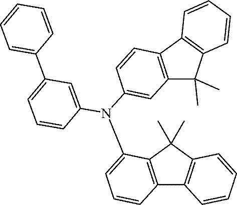 [SMILES: CC1(C)c2ccccc2-c2ccc(N(c3cccc(-c4ccccc4)c3)c3cccc4c3C(C)(C)c3ccccc3-4)cc21]

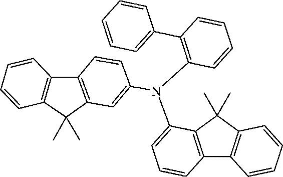 [SMILES: CC1(C)c2ccccc2-c2ccc(N(c3ccccc3-c3ccccc3)c3cccc4c3C(C)(C)c3ccccc3-4)cc21]

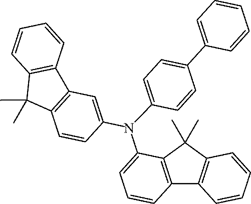 [SMILES: CC1(C)c2ccccc2-c2cc(N(c3ccc(-c4ccccc4)cc3)c3cccc4c3C(C)(C)c3ccccc3-4)ccc21]

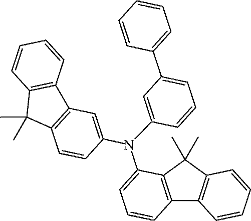 [SMILES: CC1(C)c2ccccc2-c2cc(N(c3cccc(-c4ccccc4)c3)c3cccc4c3C(C)(C)c3ccccc3-4)ccc21]

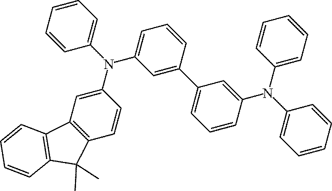 [SMILES: CC1(C)c2ccccc2-c2cc(N(c3ccccc3)c3cccc(-c4cccc(N(c5ccccc5)c5ccccc5)c4)c3)ccc21]

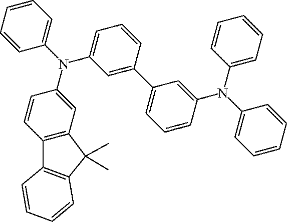 [SMILES: CC1(C)c2ccccc2-c2ccc(N(c3ccccc3)c3cccc(-c4cccc(N(c5ccccc5)c5ccccc5)c4)c3)cc21]

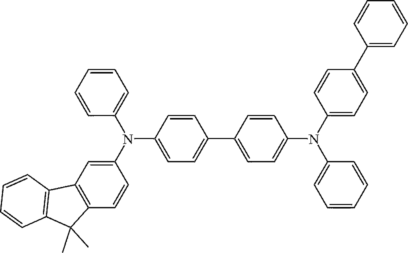 [SMILES: CC1(C)c2ccccc2-c2cc(N(c3ccccc3)c3ccc(-c4ccc(N(c5ccccc5)c5ccc(-c6ccccc6)cc5)cc4)cc3)ccc21]

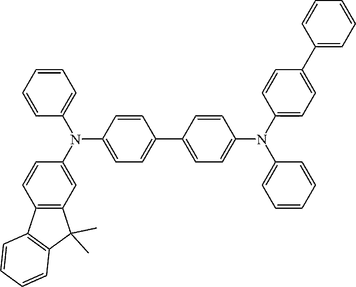 [SMILES: CC1(C)c2ccccc2-c2ccc(N(c3ccccc3)c3ccc(-c4ccc(N(c5ccccc5)c5ccc(-c6ccccc6)cc5)cc4)cc3)cc21]

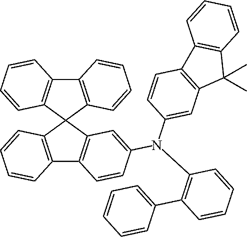 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

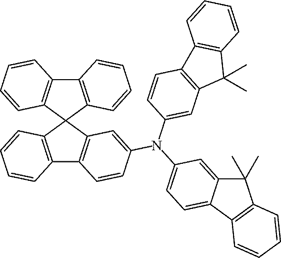 [SMILES: CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21]

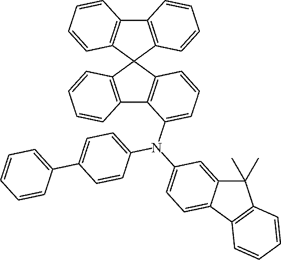 [SMILES: CC1(C)c2ccccc2-c2ccc(N(c3ccc(-c4ccccc4)cc3)c3cccc4c3-c3ccccc3C43c4ccccc4-c4ccccc43)cc21]

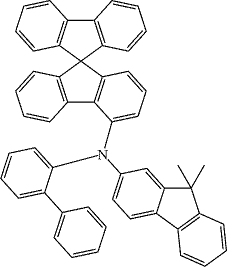 [SMILES: CC1(C)c2ccccc2-c2ccc(N(c3ccccc3-c3ccccc3)c3cccc4c3-c3ccccc3C43c4ccccc4-c4ccccc43)cc21]

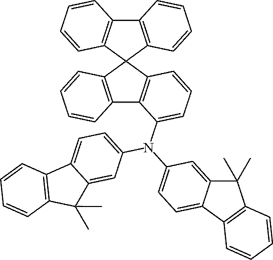 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21]

The driving voltages, efficiencies, and external quantum efficiencies of the first experimental example group (Ex1-1 to Ex1-52) are shown in Table 1 below.

TABLE 1

| Item | Structure | | Voltage (V) @ 10mA/cm² | Efficiency (cd/A) | EQE (%) |
|---|---|---|---|---|---|
| | HTL | GEH | | | |
| Ex1-1 | HM-01 | TRZ-20 | 3.42 | 59.8 | 16.4 |
| Ex1-2 | HM-02 | TRZ-20 | 3.50 | 58.5 | 16.0 |
| Ex1-3 | HM-03 | TRZ-20 | 3.56 | 59.2 | 16.2 |
| Ex1-4 | HM-04 | TRZ-20 | 3.43 | 70.1 | 19.2 |
| Ex1-5 | HM-05 | TRZ-20 | 3.59 | 58.7 | 16.1 |
| Ex1-6 | HM-06 | TRZ-20 | 3.59 | 58.6 | 16.1 |
| Ex1-7 | HM-07 | TRZ-20 | 3.42 | 60.7 | 16.6 |
| Ex1-8 | HM-08 | TRZ-20 | 3.58 | 59.7 | 16.4 |
| Ex1-9 | HM-09 | TRZ-20 | 3.59 | 68.5 | 18.8 |
| Ex1-10 | HM-10 | TRZ-20 | 3.51 | 68.1 | 18.6 |
| Ex1-11 | HM-11 | TRZ-20 | 3.53 | 70.4 | 19.3 |
| Ex1-12 | HM-12 | TRZ-20 | 3.44 | 57.8 | 15.8 |
| Ex1-13 | HM-13 | TRZ-20 | 3.40 | 71.2 | 19.5 |
| Ex1-14 | HM-14 | TRZ-20 | 3.44 | 66.7 | 18.3 |
| Ex1-15 | HM-15 | TRZ-20 | 3.51 | 57.7 | 15.8 |
| Ex1-16 | HM-16 | TRZ-20 | 3.51 | 70.4 | 19.3 |
| Ex1-17 | HM-17 | TRZ-20 | 3.57 | 64.1 | 17.6 |
| Ex1-18 | HM-18 | TRZ-20 | 3.57 | 65.8 | 18.0 |
| Ex1-19 | HM-19 | TRZ-20 | 3.50 | 70.7 | 19.4 |
| Ex1-20 | HM-20 | TRZ-20 | 3.48 | 63.2 | 17.3 |
| Ex1-21 | HM-21 | TRZ-20 | 3.55 | 69.8 | 19.1 |
| Ex1-22 | HM-22 | TRZ-20 | 3.56 | 63.2 | 17.3 |
| Ex1-23 | HM-23 | TRZ-20 | 3.41 | 63.0 | 17.3 |
| Ex1-24 | HM-24 | TRZ-20 | 3.53 | 66.3 | 18.2 |
| Ex1-25 | HM-25 | TRZ-20 | 3.41 | 63.1 | 17.3 |
| Ex1-26 | HM-01 | TRZ-01 | 3.48 | 68.7 | 18.8 |
| Ex1-27 | HM-01 | TRZ-02 | 3.56 | 70.8 | 19.4 |
| Ex1-28 | HM-01 | TRZ-03 | 3.56 | 59.0 | 16.2 |
| Ex1-29 | HM-01 | TRZ-04 | 3.41 | 62.4 | 17.1 |
| Ex1-30 | HM-01 | TRZ-05 | 3.45 | 70.7 | 19.4 |
| Ex1-31 | HM-18 | TRZ-06 | 3.46 | 60.2 | 16.5 |
| Ex1-32 | HM-18 | TRZ-07 | 3.53 | 62.2 | 17.1 |
| Ex1-33 | HM-18 | TRZ-08 | 3.57 | 57.3 | 15.7 |
| Ex1-34 | HM-18 | TRZ-09 | 3.53 | 58.2 | 15.9 |
| Ex1-35 | HM-18 | TRZ-10 | 3.41 | 63.1 | 17.3 |
| Ex1-36 | HM-18 | TRZ-11 | 3.57 | 59.1 | 16.2 |
| Ex1-37 | HM-22 | TRZ-12 | 3.50 | 59.3 | 16.2 |
| Ex1-38 | HM-22 | TRZ-13 | 3.50 | 64.7 | 17.7 |
| Ex1-39 | HM-22 | TRZ-14 | 3.51 | 65.4 | 17.9 |
| Ex1-40 | HM-22 | TRZ-15 | 3.55 | 67.1 | 18.4 |
| Ex1-41 | HM-22 | TRZ-16 | 3.44 | 59.6 | 16.3 |
| Ex1-42 | HM-22 | TRZ-17 | 3.59 | 63.7 | 17.4 |
| Ex1-43 | HM-22 | TRZ-18 | 3.53 | 62.1 | 17.0 |
| Ex1-44 | HM-22 | TRZ-19 | 3.52 | 59.8 | 16.4 |
| Ex1-45 | HM-22 | TRZ-20 | 3.48 | 64.5 | 17.7 |
| Ex1-46 | HM-22 | TRZ-21 | 3.44 | 58.7 | 16.1 |
| Ex1-47 | HM-22 | TRZ-22 | 3.43 | 59.7 | 16.4 |
| Ex1-48 | HM-22 | TRZ-23 | 3.55 | 58.1 | 15.9 |
| Ex1-49 | HM-22 | TRZ-24 | 3.45 | 68.2 | 18.7 |
| Ex1-50 | HM-22 | TRZ-25 | 3.41 | 67.1 | 18.4 |
| Ex1-51 | HM-22 | TRZ-26 | 3.50 | 59.8 | 16.4 |
| Ex1-52 | HM-22 | TRZ-27 | 3.54 | 69.2 | 18.9 |

That is, when an amine-based compound is used as the hole transport layer 12 of FIG. 3 in the first experimental example group (Ex1-1 to Ex1-52), the external quantum efficiency varies from 16% to 19.5%. It can be seen that this characteristic occurs regardless of the material of the electron-transporting host of the green light emitting layer. The second experimental example group (Ex2-1 to Ex2-71) uses the device structure of FIG. 3, but the material of the hole transport layer 12 is changed to a biscarbazole-based compound and the material for the electron-transporting host of the green light emitting layer 13 is a triazine-based compound. The results are shown in Table 2.

TABLE 2

| Item | Structure | | Voltage (V) @ 10mA/cm² | Efficiency (cd/A) | EQE (%) |
|---|---|---|---|---|---|
| | HTL | GEH | | | |
| Ex2-1 | BCA-01 | TRZ-20 | 3.57 | 82.3 | 22.5 |
| Ex2-2 | BCA-02 | TRZ-20 | 3.58 | 87.5 | 24.0 |
| Ex2-3 | BCA-03 | TRZ-20 | 3.44 | 87.0 | 23.8 |
| Ex2-4 | BCA-04 | TRZ-20 | 3.40 | 86.6 | 23.7 |
| Ex2-5 | BCA-05 | TRZ-20 | 3.59 | 87.7 | 24.0 |
| Ex2-6 | BCA-06 | TRZ-20 | 3.48 | 85.6 | 23.5 |
| Ex2-7 | BCA-07 | TRZ-20 | 3.44 | 87.0 | 23.8 |
| Ex2-8 | BCA-08 | TRZ-20 | 3.43 | 83.5 | 22.9 |
| Ex2-9 | BCA-09 | TRZ-20 | 3.55 | 90.5 | 24.8 |
| Ex2-10 | BCA-10 | TRZ-20 | 3.45 | 86.8 | 23.8 |
| Ex2-11 | BCA-11 | TRZ-20 | 3.57 | 82.5 | 22.6 |
| Ex2-12 | BCA-12 | TRZ-20 | 3.46 | 87.5 | 24.0 |
| Ex2-13 | BCA-13 | TRZ-20 | 3.51 | 89.6 | 24.5 |
| Ex2-14 | BCA-14 | TRZ-20 | 3.59 | 82.2 | 22.5 |
| Ex2-15 | BCA-15 | TRZ-20 | 3.55 | 83.2 | 22.8 |
| Ex2-16 | BCA-16 | TRZ-20 | 3.49 | 90.3 | 24.7 |
| Ex2-17 | BCA-17 | TRZ-20 | 3.54 | 88.7 | 24.3 |
| Ex2-18 | BCA-18 | TRZ-20 | 3.60 | 82.3 | 22.5 |
| Ex2-19 | BCA-19 | TRZ-20 | 3.42 | 89.6 | 24.6 |
| Ex2-20 | BCA-20 | TRZ-20 | 3.44 | 84.6 | 23.2 |
| Ex2-21 | BCA-21 | TRZ-20 | 3.48 | 85.6 | 23.4 |
| Ex2-22 | BCA-22 | TRZ-20 | 3.60 | 89.5 | 24.5 |
| Ex2-23 | BCA-23 | TRZ-20 | 3.44 | 86.4 | 23.7 |
| Ex2-24 | BCA-24 | TRZ-20 | 3.41 | 83.1 | 22.8 |
| Ex2-25 | BCA-25 | TRZ-20 | 3.51 | 86.6 | 23.7 |
| Ex2-26 | BCA-26 | TRZ-20 | 3.56 | 90.1 | 24.7 |
| Ex2-27 | BCA-27 | TRZ-20 | 3.52 | 87.4 | 23.9 |
| Ex2-28 | BCA-28 | TRZ-20 | 3.47 | 86.6 | 23.7 |
| Ex2-29 | BCA-29 | TRZ-20 | 3.58 | 87.8 | 24.1 |
| Ex2-30 | BCA-30 | TRZ-20 | 3.55 | 82.6 | 22.6 |
| Ex2-31 | BCA-31 | TRZ-20 | 3.58 | 82.8 | 22.7 |
| Ex2-32 | BCA-32 | TRZ-20 | 3.49 | 82.6 | 22.6 |
| Ex2-33 | BCA-33 | TRZ-20 | 3.46 | 88.4 | 24.2 |
| Ex2-34 | BCA-34 | TRZ-20 | 3.58 | 86.1 | 23.6 |
| Ex2-35 | BCA-35 | TRZ-20 | 3.46 | 84.1 | 23.0 |
| Ex2-36 | BCA-36 | TRZ-20 | 3.50 | 89.9 | 24.6 |
| Ex2-37 | BCA-37 | TRZ-20 | 3.58 | 85.7 | 23.5 |
| Ex2-38 | BCA-38 | TRZ-20 | 3.55 | 84.9 | 23.3 |
| Ex2-39 | BCA-39 | TRZ-20 | 3.52 | 89.2 | 24.4 |
| Ex2-40 | BCA-40 | TRZ-20 | 3.51 | 82.3 | 22.6 |
| Ex2-41 | BCA-41 | TRZ-20 | 3.44 | 87.3 | 23.9 |
| Ex2-42 | BCA-42 | TRZ-20 | 3.49 | 83.0 | 22.7 |
| Ex2-43 | BCA-43 | TRZ-20 | 3.58 | 82.1 | 22.5 |
| Ex2-44 | BCA-44 | TRZ-20 | 3.46 | 90.3 | 24.7 |
| Ex2-45 | BCA-02 | TRZ-01 | 3.42 | 84.2 | 23.1 |
| Ex2-46 | BCA-02 | TRZ-02 | 3.59 | 88.4 | 24.2 |
| Ex2-47 | BCA-02 | TRZ-03 | 3.58 | 84.1 | 23.0 |
| Ex2-48 | BCA-02 | TRZ-04 | 3.58 | 87.2 | 23.9 |
| Ex2-49 | BCA-02 | TRZ-05 | 3.46 | 87.4 | 23.9 |
| Ex2-50 | BCA-02 | TRZ-06 | 3.57 | 82.7 | 22.6 |
| Ex2-51 | BCA-02 | TRZ-07 | 3.59 | 84.0 | 23.0 |
| Ex2-52 | BCA-02 | TRZ-08 | 3.50 | 84.3 | 23.1 |
| Ex2-53 | BCA-02 | TRZ-09 | 3.47 | 85.2 | 23.3 |
| Ex2-54 | BCA-02 | TRZ-10 | 3.58 | 82.5 | 22.6 |
| Ex2-55 | BCA-02 | TRZ-11 | 3.42 | 88.7 | 24.3 |
| Ex2-56 | BCA-02 | TRZ-12 | 3.56 | 88.6 | 24.3 |
| Ex2-57 | BCA-02 | TRZ-13 | 3.53 | 88.0 | 24.1 |
| Ex2-58 | BCA-02 | TRZ-14 | 3.47 | 83.3 | 22.8 |
| Ex2-59 | BCA-02 | TRZ-15 | 3.57 | 85.3 | 23.4 |
| Ex2-60 | BCA-02 | TRZ-16 | 3.56 | 88.9 | 24.4 |
| Ex2-61 | BCA-02 | TRZ-17 | 3.41 | 89.4 | 24.5 |
| Ex2-62 | BCA-02 | TRZ-18 | 3.45 | 90.3 | 24.7 |
| Ex2-63 | BCA-02 | TRZ-19 | 3.45 | 81.6 | 22.4 |
| Ex2-64 | BCA-02 | TRZ-20 | 3.56 | 90.3 | 24.7 |
| Ex2-65 | BCA-02 | TRZ-21 | 3.40 | 85.7 | 23.5 |
| Ex2-66 | BCA-02 | TRZ-22 | 3.41 | 88.8 | 24.3 |
| Ex2-67 | BCA-02 | TRZ-23 | 3.50 | 89.0 | 24.4 |
| Ex2-68 | BCA-02 | TRZ-24 | 3.45 | 88.6 | 24.3 |
| Ex2-69 | BCA-02 | TRZ-25 | 3.52 | 89.2 | 24.4 |
| Ex2-70 | BCA-02 | TRZ-26 | 3.44 | 83.2 | 22.8 |
| Ex2-71 | BCA-02 | TRZ-27 | 3.59 | 87.9 | 24.1 |

As can be seen from Table 2, the second experimental example group (Ex2-1 to Ex2-71) had an increased external quantum efficiency (EQE) of 22% or more, unlike the first experimental example group (Ex1-1 to Ex1-52). In addition, it can be seen that the efficiency of the hole transport layer is greatly improved compared to the first experimental example group (Ex1-1 to Ex1-52), in which the hole transport layer includes an amine-based compound.

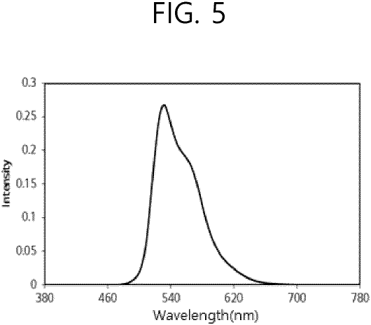

FIG. 4 is a graph showing the emission spectrum of the first experimental example group, and FIG. 5 is a graph showing the emission spectrum of the second experimental example group.

It can be seen that the intensity of emission of green light in the emission spectrum of the second experimental example group of FIG. 5 compared to FIG. 4 is increased by 25% to 30% or more, and when a triazine-based compound is used for the electron-transporting host of the single phosphorescent green light emitting layer and a biscarbazole-based compound is used for the hole-transporting host of the hole transport layer, green luminous efficiency is greatly improved.

Hereinafter, the relationship between driving voltage, efficiency, and lifespan in the structure of the third experimental example (Ex3), in which the external quantum efficiency is improved through the change in configuration, and in the structure of the fourth experimental example (Ex4), including the hole transport layer and the green light emitting layer according to the present disclosure, will be described. The third experimental example (Ex3) and the fourth experimental example (Ex4) includes a green light emitting device having a green light emitting layer as an emitting layer.

TABLE 3

| Green light emitting device | Driving voltage @100mA/cm² | Efficiency(EQE) | Lifespan |
|---|---|---|---|
| Ex3 | 7.6 V | 23.5% | 100% |
| Ex4 | 4.5 V | 16.8% | 111% |

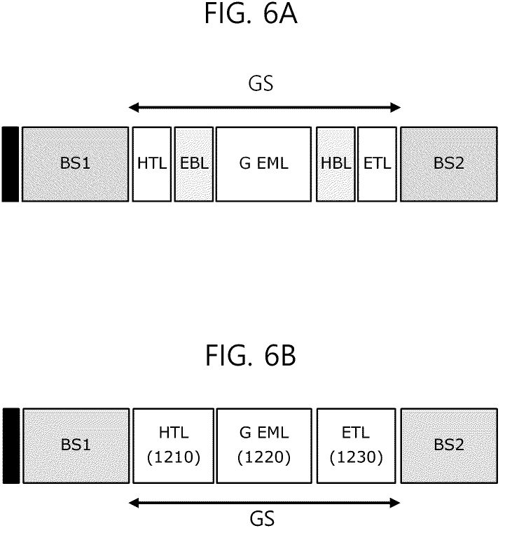

FIGS. 6A and 6B illustrate the configuration of a green phosphorescent stack GS of third and fourth experimental examples.

As shown in FIG. 6A, the green phosphorescent stack GS of the third experimental example includes an electron-blocking layer EBL between a green light emitting layer G EML and a hole transport layer HTL to prevent electrons from passing from the green light emitting layer G EML to the hole transport layer, and a hole-blocking layer HBL between the green light emitting layer G EML and the electron transport layer ETL to prevent holes from passing from the green light emitting layer G EML to the electron transport layer ETL.

Here, the hole transport layer HTL of the third experimental example Ex3 includes an amine-based compound, and the electron-transporting host in the green light emitting layer (G EML) includes a known electron-transporting host along with a phosphorescent dopant such as TPBi.

When the current density is 100 mA/cm² and the external quantum efficiency (EQE) is 23.5% in the third experimental example (Ex3), the driving voltage is 7.6V, as shown in Table 3.

As shown in FIG. 6B, in the green phosphorescent stack (GS) of the fourth experimental example (Ex4), unlike the above-described third experimental example (Ex3), the green (phosphorescent) light emitting layer (G EML) 1220 contacts the hole transport layer (HTL) 1210 and the electron transport layer (ETL) 1230, and does not include a control layer relating to hole and electron transport in addition to a separate transport layer. However, the hole transport layer (HTL) 1210 of the fourth experimental example (Ex4) includes an amine-based compound, the electron-transporting host of the green light emitting layer includes a triazine-based compound, and the materials for the first experimental group of Table 1 are used.

In this case, in the fourth experimental example (Ex4), by reducing the use of layers in the green phosphorescent stack (GS), the driving voltage is decreased to 4.5V, as shown in Table 3, which corresponds to a decrease of 41% in the driving voltage of the fourth experimental example (Ex4) compared to the third experimental example. This reduction in the driving voltage is caused by a reduction in the number of interfaces in the green phosphorescent stack GS.

In addition, the lifespan is improved to 111%, which corresponds to an 11% increase compared to the third experimental example.

Meanwhile, as shown in Table 2, when the material for the hole transport layer that is in contact with the green light emitting layer 1220 is a biscarbazole-based compound, unlike the first experimental example, electrons and holes are confined and are thus likely to be combined together inside the green light emitting layer 1220. It can be seen from this that the effects of reducing the driving voltage, prolonging the lifespan, and increasing efficiency can be obtained using a biscarbazole-based compound as the material of a hole transport layer and using a triazine-based compound as the material for an electron-transporting host of a green light emitting layer contacting the same in a green phosphorescent stack including at least one green light emitting layer.

Hereinafter, an example in which a light emitting device has a four-stack structure of FIG. 1 including the above-described green phosphorescent stack will be described

FIG. 7 is a cross-sectional view illustrating light emitting devices according to fifth to seventh experimental examples of the present disclosure.

As shown in FIG. 7, an internal stack OS between a first electrode 110 and a second electrode 200 in the light emitting device OLED of the present disclosure has a red stack RS, a first charge generation layer CGL1, a first blue stack BS1, a second charge generation layer CGL2, a green stack GS, a third charge generation layer CGL3, and a second blue stack BS2, which are stacked on the first electrode 110 in that order.

Here, the red stack RS and the green stack GS are phosphorescent stacks and the first and second blue stacks BS1 and BS2 are fluorescent stacks.

The red stack RS includes a hole injection layer (HIL) 121, a first hole transport layer (HTL1) 122, a red light emitting layer (R EML) 123, and a first electron transport layer (ETL1) 124, which are stacked in that order on the first electrode 110.

The first to third charge generation layers CGL1, CGL2, and CGL3 include n-type charge generation layers nCGL1, nCGL2, and nCGL3 and p-type charge generation layers pCGL1, pCGL2, and pCGL3, respectively.

The first blue stack BS1 is formed on the first charge generation layer CGL1, and includes a second hole transport layer (HTL2) 131, a first electron-blocking layer (EBL1) 132, a first blue light emitting layer (B EML1) 133, and a second electron transport layer (ETL2) 134.

In addition, the green stack GS includes a third hole transport layer (HTL3) 141, a green light emitting layer (G EML) 142, and a third electron transport layer (ETL3) 143.

The second blue stack BS2 is formed on the third charge generation layer CGL3, and includes a fourth hole transport layer (HTL4) 151, a second electron-blocking layer (EBL2) 152, a second blue light emitting layer (B EML2) 153, and a fourth electron transport layer (ETL4) 154.

Here, the first and second blue stacks BS1 and BS2 include first and second electron-blocking layers 132 and 152, respectively, unlike the other color stacks, and the first and second electron-blocking layers 132 and 152 are formed using a material with a high mobility rate to increase efficiency comparable to adjacent phosphorescent stacks in order to prevent electrons from passing from the electron transport layers 134 and 154 to hole transport layers 131 and 151. In some cases, the material of the hole transport layers 131 and 151 may be changed or omitted.

The fifth to seventh experimental examples were conducted by changing the material of the third hole transport layer 141 and the electron-transporting host in the green light emitting layer 142 of the green stack GS, and the remaining layers were the same.

TABLE 4

| Item | | Ex5 | Ex6 | Ex7 |
|---|---|---|---|---|
| Efficiency | R [Cd/A] | 14.3 | 13.6 | 14.2 |
| | G[Cd/A] | 39.5 | 28.8 | 40.3 |
| | B[Cd/A] | 5.2 | 4.8 | 5.3 |
| | EQE (%) | 45.6 | 40.2 | 46.0 |
| Driving voltage | V | 21.5 | 17.4 | 17.5 |
| Color coordinates | Rx | 0.692 | 0.693 | 0.692 |
| | Ry | 0.306 | 0.305 | 0.307 |
| | Gx | 0.276 | 0.272 | 0.276 |
| | Gy | 0.692 | 0.690 | 0.692 |
| | Bx | 0.148 | 0.147 | 0.148 |
| | By | 0.060 | 0.054 | 0.060 |
| | Wx | 0.341 | 0.332 | 0.339 |
| | Wy | 0.355 | 0.313 | 0.355 |

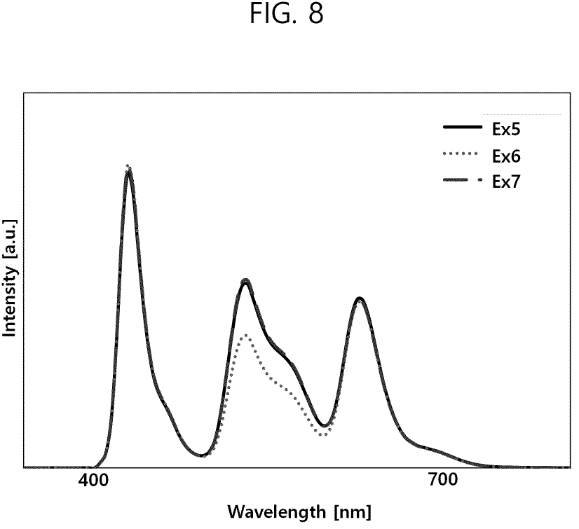

FIG. 8 is a graph showing white emission spectra of light emitting devices according to fifth to seventh experimental examples of FIG. 7.

In the fifth experimental example (Ex5) and the sixth experimental example (Ex6), like Ex1-15 of the first experimental example group, the third hole transport layer 141 includes HM-15 and an electron-transporting host (GEH) of the green light emitting layer 142 is TRZ-20. However, in the fifth experimental example (Ex5), the electron-blocking layer (EBL) and the hole-blocking layer (HBL) are additionally formed so as to contact the green light emitting layer 142 to improve efficiency.

In the seventh experimental example (Ex7), the third hole transport layer 141 includes BCA-03 and the electron-transporting host GEH of the green light emitting layer 142 is TRZ-20.

In the fifth experimental example (Ex5), as shown in FIG. 8, particularly, the effect of improving green efficiency is obtained, but as shown in Table 4, the driving voltage is increased by 4V or more compared to the sixth experimental example (Ex6). That is, it has a structure in which the driving voltage is increased and lifespan is affected by high power consumption when driven for a long time.

In the sixth experimental example (Ex6) , the driving voltage is improved, and there is a difference of 10.7 Cd/A in green efficiency from the fifth experimental example (Ex5). Green plays an important role in realizing white. Therefore, upon implementing a white-light emitting device, a compensation means, in addition to a light emitting device, is required to obtain the desired white luminance.

In contrast, in the light emitting device of the present disclosure, in the seventh experimental example (Ex7), efficiency is improved to a level comparable to the fifth experimental example (Ex5), and the driving voltage is comparable to the sixth experimental example (Ex6) having the same layered structure, but green efficiency is improved by 11.5 Cd/A or more. It can be seen that efficiency can be improved even at a decreased driving voltage when a white-light emitting device is implemented. This means that the device can be driven at a low driving voltage for a long period of time, which directly affects the improvement in lifespan.

Hereinafter, another example of the light emitting device of the present disclosure will be described.

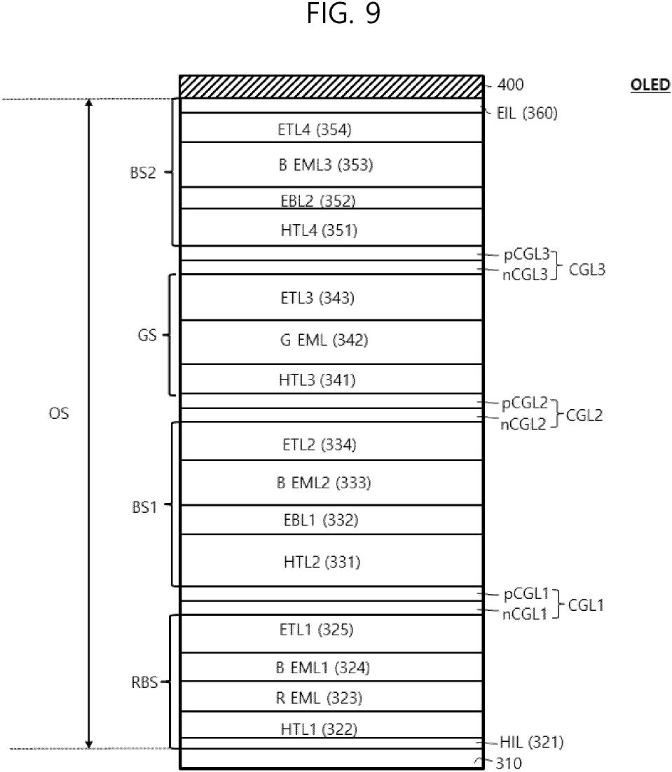

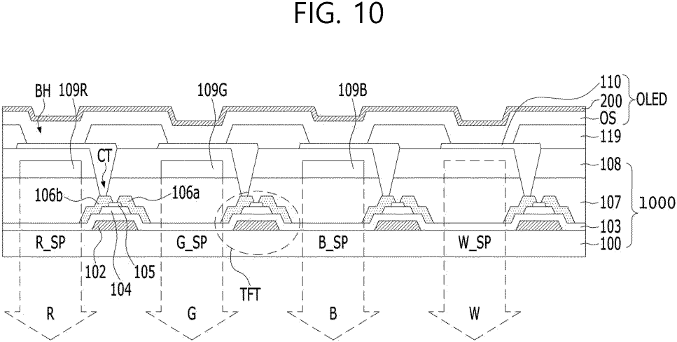

FIG. 9 is a cross-sectional view illustrating a light emitting device according to another embodiment of the present disclosure.

As shown in FIG. 9, a red-blue stack RBS of an internal stack OS between a first electrode 310 and a second electrode 400 in the light emitting device according to another embodiment of the present disclosure includes a first blue light emitting layer (B EML1) 324 in contact with a red light emitting layer (R EML) 323, and a first electron transport layer (ETL1) 325 disposed thereon, and a first hole transport layer (HTL1) 322 disposed under the red light emitting layer (R EML) 323, in contrast with the light emitting device of FIG. 7. The light emitting device further includes the blue light emitting layer 324 in contact with the red light emitting layer 323, which is the phosphorescent light emitting layer, to satisfy the requirement to improve the color temperature.

In this case, the first and second blue stacks BS1 and BS2 include hole transport layers (HTL2, HTL4) 331 and 351, electron-blocking layers (EBL1, EBL2) 332 and 352, blue light emitting layers (B EML2, B EML3) 333 and 353, and electron transport layers (ETL2, ETL4) 334 and 354, respectively. The second blue stack BS2 in contact with the second electrode 400 further includes an electron injection layer (EIL)360.

In addition, as described with reference to FIG. 7, the green stack GS has a simple configuration including a hole transport layer (HTL3) 341, a green light emitting layer (G EML) 342, and an electron transport layer (ETL3) 343. As described above, the green stack GS is driven through a simple configuration and is capable of exerting effects of improving efficiency, reducing the driving voltage, and prolonging the lifespan by changing the materials of the hole-transporting host in the hole transport layer 341 and electron-transporting host in the green light emitting layer 342.

Hereinafter, an example of a light emitting display device using the light emitting device of the present disclosure will be described.

FIG. 10 is a sectional view illustrating the light emitting display device using the light emitting device according to an embodiment of the present disclosure.

As shown in FIG. 10, the light emitting display device of the present disclosure includes a substrate 100 having a plurality of subpixels R_SP, G_SP, B_SP, and W_SP emitting red light R, green light G, blue light B and white light W, respectively, a light emitting device (also referred to as an “OLED, organic light emitting diode”) commonly provided on the substrate 100, a thin film transistor TFT provided at each of the subpixels and connected to the first electrode 110 of the light emitting device OLED, and a color filter layer 109R, 109G, or 109B provided below the first electrode 110 of at least one of the subpixels.

The illustrated example relates to a configuration including the white subpixel W_SP, but the present disclosure is not limited thereto. A configuration in which the white subpixel W_SP is omitted and only the red, green, and blue subpixels R_SP, G_SP, and B_SP are provided is also possible. In some cases, a combination of a cyan subpixel, a magenta subpixel, and a yellow subpixel capable of creating white may be used instead of the red, green, and blue subpixels.

The thin film transistor TFT includes, for example, a gate electrode 102, a semiconductor layer 104, and a source electrode 106a and a drain electrode 106b connected to respective sides of the semiconductor layer 104. In addition, a channel passivation layer 105 may be further provided on the portion where the channel of the semiconductor layer 104 is located in order to prevent direct connection between the source/drain electrodes 106a and 106b and the semiconductor layer 104.

A gate insulating layer 103 is provided between the gate electrode 102 and the semiconductor layer 104.

The semiconductor layer 104 may be formed of, for example, an oxide semiconductor, amorphous silicon, polycrystalline silicon, or a combination thereof. For example, when the semiconductor layer 104 is an oxide semiconductor, the heating temperature required for forming the thin film transistor can be lowered, and thus the substrate 100 can be selected from among a greater variety of available types thereof, so the semiconductor layer 104 can be advantageously applied to a flexible display.

In addition, the drain electrode 106b of the thin film transistor TFT may be connected to the first electrode 110 in a contact hole CT formed in the first and second passivation layers 107 and 108.

The first passivation layer 107 is provided to primarily protect the thin film transistor TFT, and the color filter layers 109R, 109G, and 109B may be provided thereon.

When the plurality of subpixels includes a red subpixel, a green subpixel, a blue subpixel, and a white subpixel, the color filter layer may include first to third color filter layers 109R, 109G, and 109B in each of the remaining subpixels, excluding the white subpixel W_SP, and may allow the emitted white light to pass through the first electrode 110 for each wavelength. A second passivation layer 108 is formed under the first electrode 110 to cover the first to third color filter layers 109R, 109G, and 109B. The first electrode 110 is formed on the surface of the second passivation layer 108 and connected to the thin film transistor TFT through the contact hole CT.

Here, the configuration beneath the first electrode 110, including the substrate 100, the thin film transistor TFT, the color filter layers 109R, 109G, and 109B, and the first and second passivation layers 107 and 108 is referred to as a “thin film transistor array substrate” 1000.

The light emitting device OLED is formed on the thin film transistor array substrate 1000 including a bank 119 defining a light emitting region BH. The light emitting device OLED includes, for example, a transparent first electrode 110, a second electrode 200 of a reflective electrode opposite thereto, and a single green light emitting layer in a green phosphorescent stack between the first electrode 110 and the second electrode 200. As described above, the hole transporting host of the hole transport layer in contact with the green light emitting layer is a biscarbazole compound represented by Formula 2, and the material of the electron-transporting host in the green light emitting layer is a triazine-based compound represented by Formula 1, so effects of improving efficiency, reducing driving voltage and improving lifetime can be obtained.

According to the light emitting device of the present disclosure and a light emitting display device including the same, a fluorescent stack is connected to a phosphorescent stack to form a light emitting device that realizes white. Among them, the phosphorescent stack shares the use of excitons with other phosphorescent light emitting layers in contact with the same at higher internal quantum efficiency than the fluorescent stack. The light emitting device and the light emitting display device including the same according to the present disclosure are capable of preventing exciton loss at the interface with the hole transport layer by changing the material of the red light emitting layer between the hole transport layer and the other phosphorescent layer and evenly distributing the generation of excitons in the adjacent phosphorescent layers, thereby uniformly improving the white efficiency of the adjacent phosphorescent layers.

As a result, by balancing the efficiency between the red light emitting layer and the adjacent phosphorescent light emitting layer, the luminance of the phosphorescent light emitting layers in the white-light emitting device can be increased in a balanced way and the efficiency of the light emitting display device can also be improved.

In one embodiment of the present disclosure, a light emitting device includes a first electrode and a second electrode facing each other, and a light emitting unit including a p-type charge generation layer, a hole transport layer, and a green light emitting layer sequentially stacked, wherein the green light emitting layer includes a first material represented by the following Formula 1 and a phosphorescent dopant,

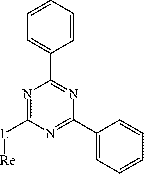

wherein Re may include at least one of a dibenzofuran group, a dibenzothiophene group, a triphenyl group, a triphenylene group, a carbazole group, a benzocarbazole group, a biscarbazole group, an indenocarbazole group, a fluoeine group and a phenyl-carbazole group. L may be a single bond or may include at least one of a phenyl group, a phenylene group, a biphenyl group, a biphenylene group, a dibenzofuran group, a dibenzofurylene group, a dibenzofurylene group, a dibenzothiophene and a dibenzothienylene group.

The hole transport layer may include a second material represented by Formula 2:

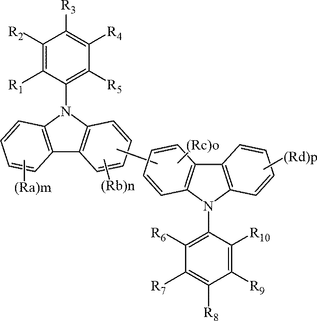

wherein Ra to Rd are each independently selected from hydrogen, deuterium, halogen, a substituted or unsubstituted C1-C6 alkyl group, a substituted or unsubstituted C3-C6 cycloalkyl group, a substituted or unsubstituted C6-C15 aryl group, a substituted or unsubstituted C5-C9 heteroaryl group, a carbazole group, a dibenzofuran group, a dibenzothiophene group, a trialkylsilyl group, and a triarylsilyl group, m and p are each independently selected from integers from 0 to 4, n and o are each independently selected from integers from 0 to 3, and R₁ to R₁₀ are each independently selected from hydrogen, deuterium, halogen, a substituted or unsubstituted C1-C6 alkyl group, a substituted or unsubstituted C6-C18 aryl group, a carbazole group, a phenyl-carbazole group, a dibenzofuran group, and a dibenzothiophene group; or two or more of R₁ to R₁₀ together with the phenyl group that they are connected with may form a condensed aryl group.

The phosphorescent dopant may be a metal complex compound having an emission peak at a wavelength of 510 nm to 550 nm.

A side of the green light emitting layer that is not in contact with the hole transport layer may be in contact with the electron transport layer.

A side of the electron transport layer that is not in contact with the green light emitting layer may be in contact with an electron injection layer or an n-type charge generation layer.

A side of the electron transport layer that is not in contact with the green light emitting layer may be in contact with an organic layer doped with a metal or an inorganic layer containing a metal compound.

At least one of the p-type charge generation layer and the n-type charge generation layer may be adjacent to a blue stack including a blue light emitting layer, and the blue light emitting layer may include a blue dopant having an emission peak at a wavelength of 420 nm to 480 nm.

The p-type charge generation layer may be spaced at a distance of 50 nm or more from the first electrode.

In another embodiment of the present disclosure, a light emitting device includes a first electrode and a second electrode facing each other, and a light emitting unit including a p-type charge generation layer, a hole transport layer, a green light emitting layer and an electron transport layer sequentially stacked, wherein the green light emitting layer includes a first material represented by the above Formula 1 and a phosphorescent dopant, and the hole transport layer includes a biscarbazole-based compound as a second material.

In another embodiment of the present disclosure, a light emitting device includes a first electrode and a second electrode facing each other, and a red stack, a first blue stack, a green stack, and a second blue stack sequentially disposed between the first electrode and the second electrode, wherein the green stack sequentially includes a hole transport layer, a green light emitting layer, and an electron transport layer, wherein the green light emitting layer includes a first material represented by the above Formula 1 and a phosphorescent dopant, and the hole transport layer includes a biscarbazole-based compound as a second material.

In another embodiment of the present disclosure, a light emitting display device includes a substrate including a plurality of subpixels, a thin film transistor provided at each of the subpixels on the substrate, and the light emitting device connected to the thin film transistor.

The light emitting device and the light emitting display device according to the present disclosure have the following effects.

In a light emitting device having a single light emitting layer in each stack in order to improve luminance, efficiency is improved without forming a separate control layer around a green phosphorescent layer by changing the physical properties of the green phosphorescent layer and the hole transport layer adjacent to the green stack having a single green phosphorescent layer.

In addition, luminance of white is improved by improving the efficiency of the green stack, which contributes most to realizing white. In addition, when the white luminance is improved under the condition that the same voltage is applied, the voltage required to realize a predetermined luminance is reduced, so the turn-on voltage is reduced over time and thus the lifespan is improved.

It will be apparent to those skilled in the art that various modifications and variations can be made in the present disclosure without departing from the spirit or scope of the disclosure. Thus, it is intended that the present disclosure covers such modifications and variations thereto, provided they fall within the scope of the appended claims and their equivalents.

What is claimed is:

1. A light emitting device comprising:
a first electrode and a second electrode facing each other; and
a light emitting unit comprising a p-type charge generation layer, a hole transport layer, and a green light emitting layer sequentially stacked,
wherein the green light emitting layer comprises a first material represented by the following Formula 1 and a phosphorescent dopant, 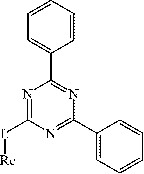
wherein Re includes at least one of a dibenzofuran group, a dibenzothiophene group, a triphenyl group, a triphenylene group, a carbazole group, a benzocarbazole group, an indenocarbazole group, a biscarbazole group, a fluorene group and a phenyl-carbazole group; and
L is a single bond or includes at least one of a phenyl group, a phenylene group, a biphenyl group, a biphenylene group, a dibenzofuran group, a dibenzofurylene group, a dibenzothiophene group and a dibenzothienylene.

2. The light emitting device according to claim 1, wherein the hole transport layer comprises a second material of Formula 2: 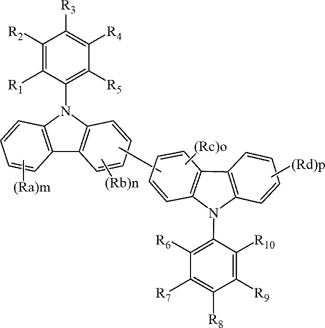
wherein Ra to Rd are each independently selected from hydrogen, deuterium, halogen, a substituted or unsubstituted C1-C6 alkyl group, a substituted or unsubstituted C3-C6 cycloalkyl group, a substituted or unsubstituted C6-C15 aryl group, a substituted or unsubstituted C5-C9 heteroaryl group, a carbazole group, a dibenzofuran group, a dibenzothiophene group, a trialkylsilyl group, and a triarylsilyl group;
m and p are each independently selected from integers from 0 to 4;
n and o are each independently selected from integers from 0 to 3; and
R₁ to R₁₀ are each independently selected from hydrogen, deuterium, halogen, a substituted or unsubstituted C1-C6 alkyl group, a substituted or unsubstituted C6-C18 aryl group, a carbazole group, a phenyl-carbazole group, a dibenzofuran group, and a dibenzothiophene group; or two or more of R₁ to R₁₀ together with the phenyl group that they are connected with may form a condensed aryl group.

3. The light emitting device according to claim 1, wherein the phosphorescent dopant is a metal complex compound having an emission peak at a wavelength of 510 nm to 550 nm.

4. The light emitting device according to claim 1, wherein a side of the green light emitting layer that is not in contact with the hole transport layer is in contact with an electron transport layer.

5. The light emitting device according to claim 4, wherein a side of the electron transport layer that is not in contact with the green light emitting layer is in contact with an electron injection layer or an n-type charge generation layer.

6. The light emitting device according to claim 4, wherein an organic layer doped with a metal or an inorganic layer containing a metal compound is in contact with the side of the electron transport layer that is not in contact with the green light emitting layer.

7. The light emitting device according to claim 5, wherein at least one of the p-type charge generation layer and the n-type charge generation layer is adjacent to a blue stack including a blue light emitting layer, and
the blue light emitting layer comprises a blue dopant having an emission peak at a wavelength of 420 nm to 480 nm.

8. The light emitting device according to claim 1, wherein the p-type charge generation layer is spaced at a distance of 50 nm or more from the first electrode.

9. The light emitting device according to claim 1, wherein the material of Formula 1 is one of the following compounds TRZ-01 to TRZ-27: 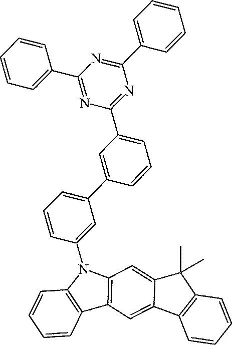 [SMILES: CC1(C)c2ccccc2-c2cc3c4ccccc4n(-c4cccc(-c5cccc(-c6nc(-c7ccccc7)nc(-c7ccccc7)n6)c5)c4)c3cc21] 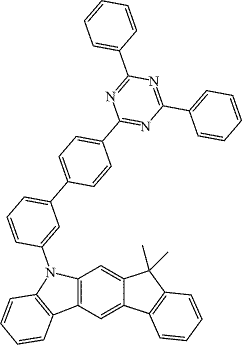 [SMILES: CC1(C)c2ccccc2-c2cc3c4ccccc4n(-c4cccc(-c5ccc(-c6nc(-c7ccccc7)nc(-c7ccccc7)n6)cc5)c4)c3cc21] 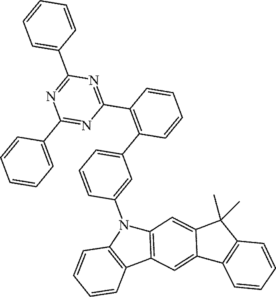 [SMILES: CC1(C)c2ccccc2-c2cc3c4ccccc4n(-c4cccc(-c5ccccc5-c5nc(-c6ccccc6)nc(-c6ccccc6)n5)c4)c3cc21] 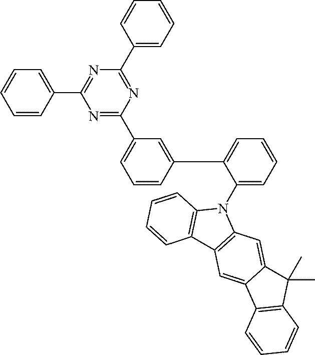 [SMILES: CC1(C)c2ccccc2-c2cc3c4ccccc4n(-c4ccccc4-c4cccc(-c5nc(-c6ccccc6)nc(-c6ccccc6)n5)c4)c3cc21] 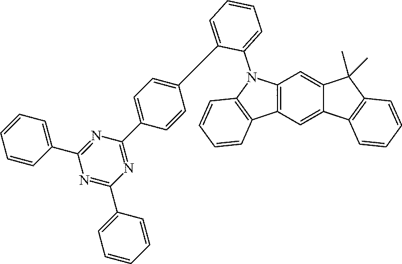 [SMILES: CC1(C)c2ccccc2-c2cc3c4ccccc4n(-c4ccccc4-c4ccc(-c5nc(-c6ccccc6)nc(-c6ccccc6)n5)cc4)c3cc21] 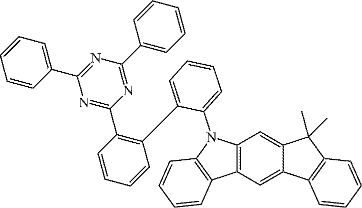 [SMILES: CC1(C)c2ccccc2-c2cc3c4ccccc4n(-c4ccccc4-c4ccccc4-c4nc(-c5ccccc5)nc(-c5ccccc5)n4)c3cc21] 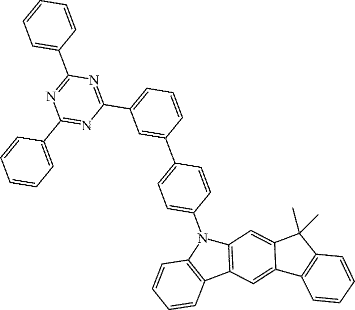 [SMILES: CC1(C)c2ccccc2-c2cc3c4ccccc4n(-c4ccc(-c5cccc(-c6nc(-c7ccccc7)nc(-c7ccccc7)n6)c5)cc4)c3cc21] 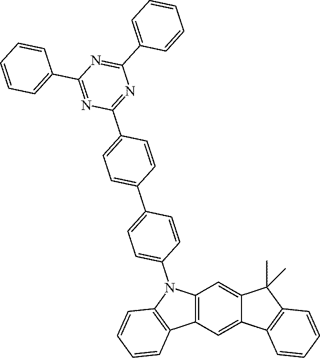 [SMILES: CC1(C)c2ccccc2-c2cc3c4ccccc4n(-c4ccc(-c5ccc(-c6nc(-c7ccccc7)nc(-c7ccccc7)n6)cc5)cc4)c3cc21] 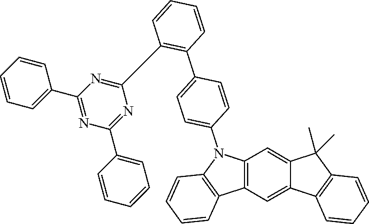 [SMILES: CC1(C)c2ccccc2-c2cc3c4ccccc4n(-c4ccc(-c5ccccc5-c5nc(-c6ccccc6)nc(-c6ccccc6)n5)cc4)c3cc21] 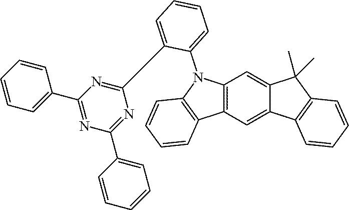 [SMILES: CC1(C)c2ccccc2-c2cc3c4ccccc4n(-c4ccccc4-c4nc(-c5ccccc5)nc(-c5ccccc5)n4)c3cc21] 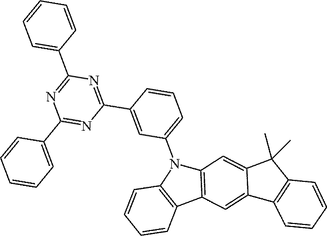 [SMILES: CC1(C)c2ccccc2-c2cc3c4ccccc4n(-c4cccc(-c5nc(-c6ccccc6)nc(-c6ccccc6)n5)c4)c3cc21] 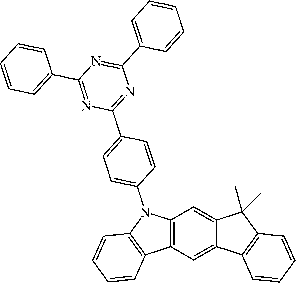 [SMILES: CC1(C)c2ccccc2-c2cc3c4ccccc4n(-c4ccc(-c5nc(-c6ccccc6)nc(-c6ccccc6)n5)cc4)c3cc21] 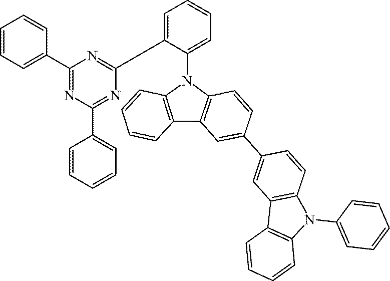 [SMILES: c1ccc(-c2nc(-c3ccccc3)nc(-c3ccccc3-n3c4ccccc4c4cc(-c5ccc6c(c5)c5ccccc5n6-c5ccccc5)ccc43)n2)cc1] 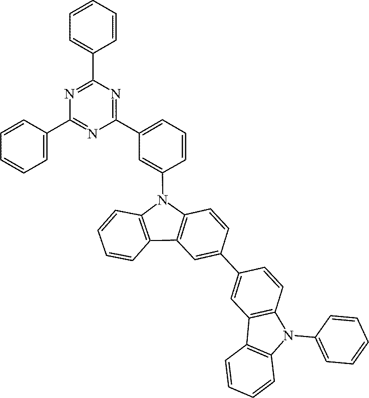 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1] 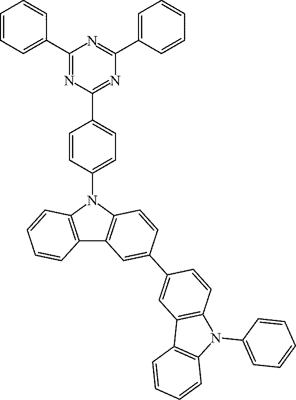 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1] 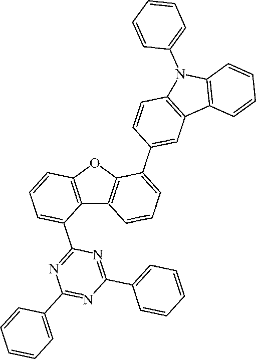 [SMILES: c1ccc(-c2nc(-c3ccccc3)nc(-c3cccc4oc5c(-c6ccc7c(c6)c6ccccc6n7-c6ccccc6)cccc5c34)n2)cc1] 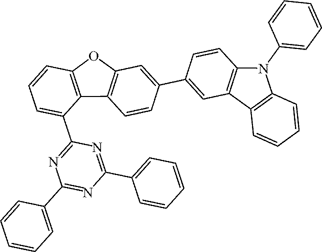 [SMILES: c1ccc(-c2nc(-c3ccccc3)nc(-c3cccc4oc5cc(-c6ccc7c(c6)c6ccccc6n7-c6ccccc6)ccc5c34)n2)cc1] 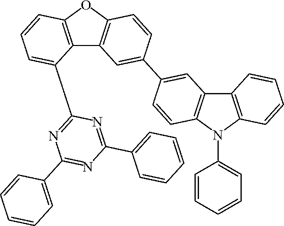 [SMILES: c1ccc(-c2nc(-c3ccccc3)nc(-c3cccc4oc5ccc(-c6ccc7c(c6)c6ccccc6n7-c6ccccc6)cc5c34)n2)cc1] 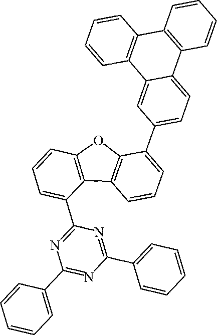 [SMILES: c1ccc(-c2nc(-c3ccccc3)nc(-c3cccc4oc5c(-c6ccc7c8ccccc8c8ccccc8c7c6)cccc5c34)n2)cc1] 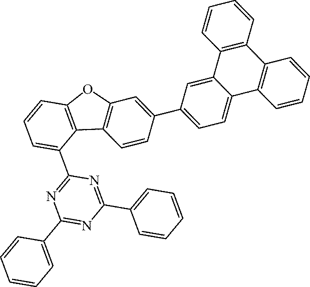 [SMILES: c1ccc(-c2nc(-c3ccccc3)nc(-c3cccc4oc5cc(-c6ccc7c8ccccc8c8ccccc8c7c6)ccc5c34)n2)cc1] 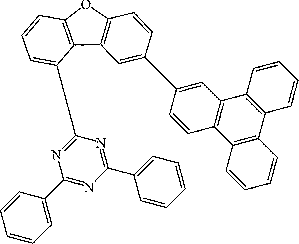 [SMILES: c1ccc(-c2nc(-c3ccccc3)nc(-c3cccc4oc5ccc(-c6ccc7c8ccccc8c8ccccc8c7c6)cc5c34)n2)cc1] 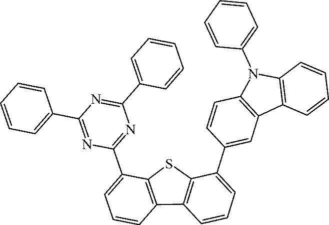 [SMILES: c1ccc(-c2nc(-c3ccccc3)nc(-c3cccc4c3sc3c(-c5ccc6c(c5)c5ccccc5n6-c5ccccc5)cccc34)n2)cc1] 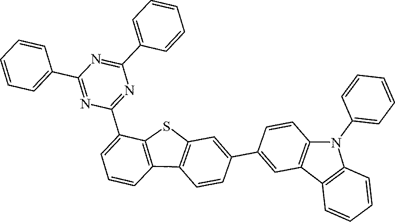 [SMILES: c1ccc(-c2nc(-c3ccccc3)nc(-c3cccc4c3sc3cc(-c5ccc6c(c5)c5ccccc5n6-c5ccccc5)ccc34)n2)cc1] 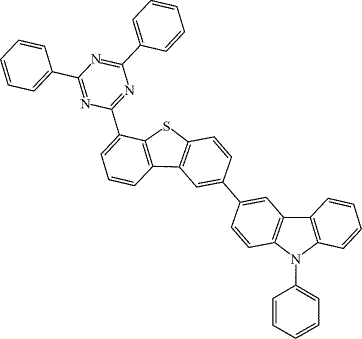 [SMILES: c1ccc(-c2nc(-c3ccccc3)nc(-c3cccc4c3sc3ccc(-c5ccc6c(c5)c5ccccc5n6-c5ccccc5)cc34)n2)cc1] 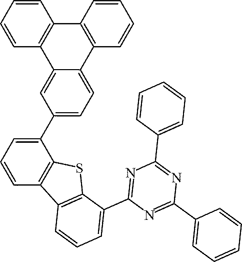 [SMILES: c1ccc(-c2nc(-c3ccccc3)nc(-c3cccc4c3sc3c(-c5ccc6c7ccccc7c7ccccc7c6c5)cccc34)n2)cc1] 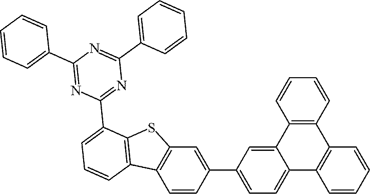 [SMILES: c1ccc(-c2nc(-c3ccccc3)nc(-c3cccc4c3sc3cc(-c5ccc6c7ccccc7c7ccccc7c6c5)ccc34)n2)cc1] 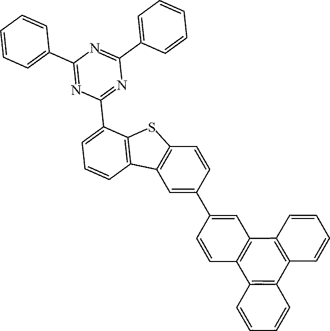 [SMILES: c1ccc(-c2nc(-c3ccccc3)nc(-c3cccc4c3sc3ccc(-c5ccc6c7ccccc7c7ccccc7c6c5)cc34)n2)cc1]
.

10. The light emitting device according to claim 2, wherein the material of Formula 2 is one of the following compounds BCA-01 to BCA-44: 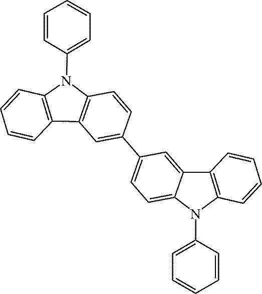 [SMILES: c1ccc(-n2c3ccccc3c3cc(-c4ccc5c(c4)c4ccccc4n5-c4ccccc4)ccc32)cc1] 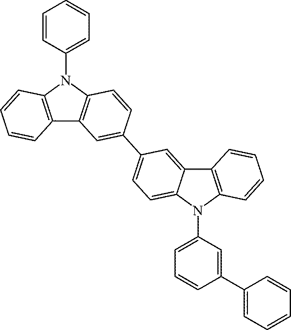 [SMILES: c1ccc(-c2cccc(-n3c4ccccc4c4cc(-c5ccc6c(c5)c5ccccc5n6-c5ccccc5)ccc43)c2)cc1] 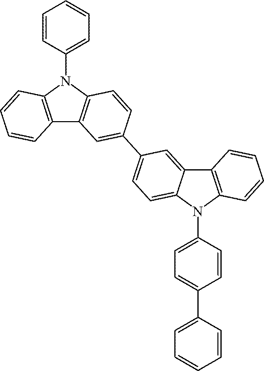 [SMILES: c1ccc(-c2ccc(-n3c4ccccc4c4cc(-c5ccc6c(c5)c5ccccc5n6-c5ccccc5)ccc43)cc2)cc1] 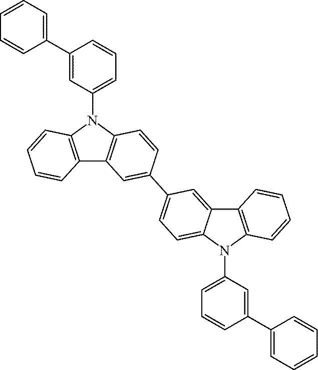 [SMILES: c1ccc(-c2cccc(-n3c4ccccc4c4cc(-c5ccc6c(c5)c5ccccc5n6-c5cccc(-c6ccccc6)c5)ccc43)c2)cc1] 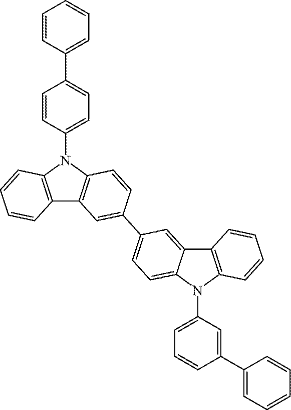 [SMILES: c1ccc(-c2ccc(-n3c4ccccc4c4cc(-c5ccc6c(c5)c5ccccc5n6-c5cccc(-c6ccccc6)c5)ccc43)cc2)cc1] 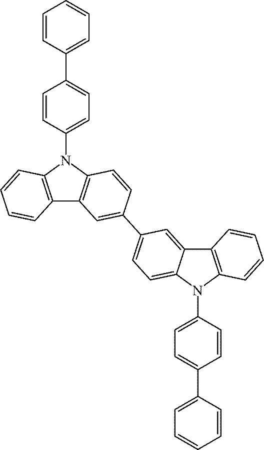 [SMILES: c1ccc(-c2ccc(-n3c4ccccc4c4cc(-c5ccc6c(c5)c5ccccc5n6-c5ccc(-c6ccccc6)cc5)ccc43)cc2)cc1] 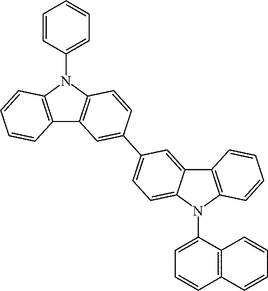 [SMILES: c1ccc(-n2c3ccccc3c3cc(-c4ccc5c(c4)c4ccccc4n5-c4cccc5ccccc45)ccc32)cc1] 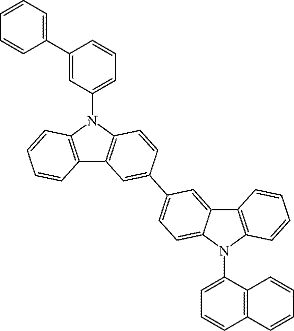 [SMILES: c1ccc(-c2cccc(-n3c4ccccc4c4cc(-c5ccc6c(c5)c5ccccc5n6-c5cccc6ccccc56)ccc43)c2)cc1] 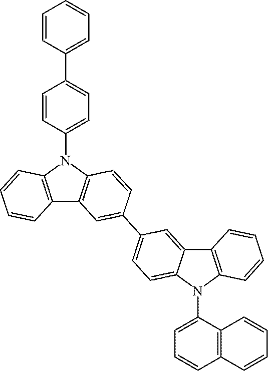 [SMILES: c1ccc(-c2ccc(-n3c4ccccc4c4cc(-c5ccc6c(c5)c5ccccc5n6-c5cccc6ccccc56)ccc43)cc2)cc1] 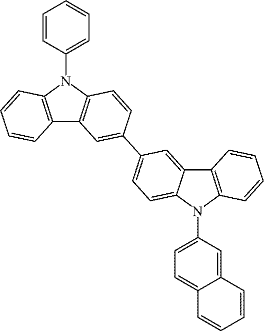 [SMILES: c1ccc(-n2c3ccccc3c3cc(-c4ccc5c(c4)c4ccccc4n5-c4ccc5ccccc5c4)ccc32)cc1] 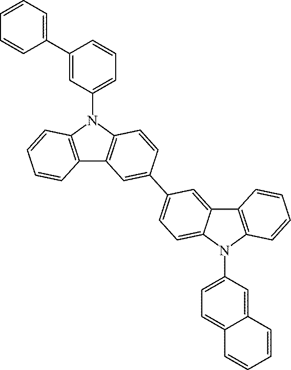 [SMILES: c1ccc(-c2cccc(-n3c4ccccc4c4cc(-c5ccc6c(c5)c5ccccc5n6-c5ccc6ccccc6c5)ccc43)c2)cc1] 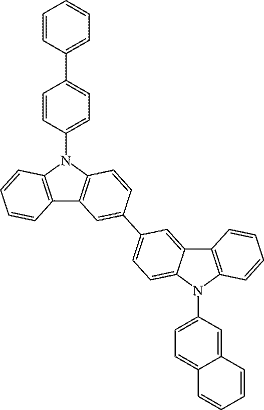 [SMILES: c1ccc(-c2ccc(-n3c4ccccc4c4cc(-c5ccc6c(c5)c5ccccc5n6-c5ccc6ccccc6c5)ccc43)cc2)cc1] 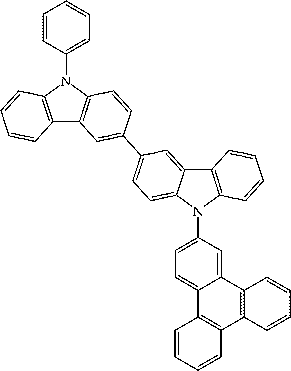 [SMILES: c1ccc(-n2c3ccccc3c3cc(-c4ccc5c(c4)c4ccccc4n5-c4ccc5c6ccccc6c6ccccc6c5c4)ccc32)cc1] 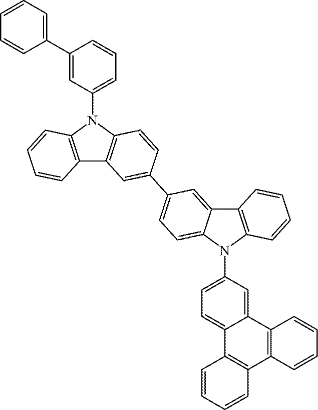 [SMILES: c1ccc(-c2cccc(-n3c4ccccc4c4cc(-c5ccc6c(c5)c5ccccc5n6-c5ccc6c7ccccc7c7ccccc7c6c5)ccc43)c2)cc1] 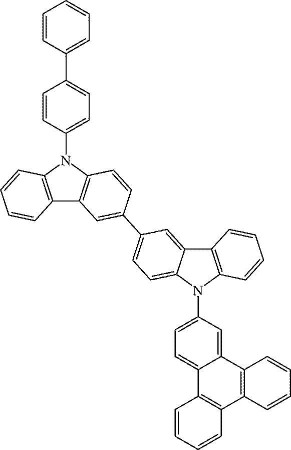 [SMILES: c1ccc(-c2ccc(-n3c4ccccc4c4cc(-c5ccc6c(c5)c5ccccc5n6-c5ccc6c7ccccc7c7ccccc7c6c5)ccc43)cc2)cc1] 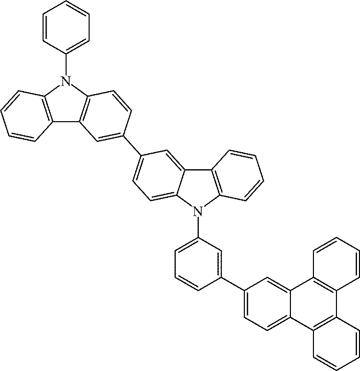 [SMILES: c1ccc(-n2c3ccccc3c3cc(-c4ccc5c(c4)c4ccccc4n5-c4cccc(-c5ccc6c7ccccc7c7ccccc7c6c5)c4)ccc32)cc1] 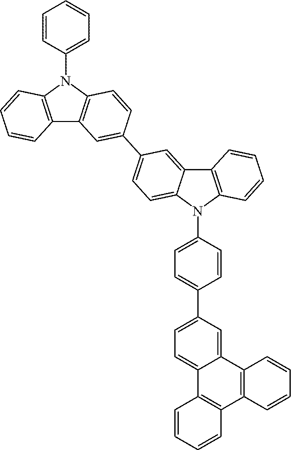 [SMILES: c1ccc(-n2c3ccccc3c3cc(-c4ccc5c(c4)c4ccccc4n5-c4ccc(-c5ccc6c7ccccc7c7ccccc7c6c5)cc4)ccc32)cc1] 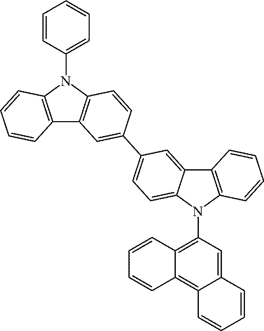 [SMILES: c1ccc(-n2c3ccccc3c3cc(-c4ccc5c(c4)c4ccccc4n5-c4cc5ccccc5c5ccccc45)ccc32)cc1] 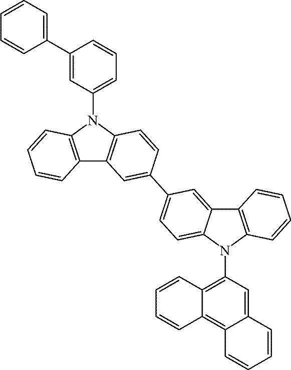 [SMILES: c1ccc(-c2cccc(-n3c4ccccc4c4cc(-c5ccc6c(c5)c5ccccc5n6-c5cc6ccccc6c6ccccc56)ccc43)c2)cc1] 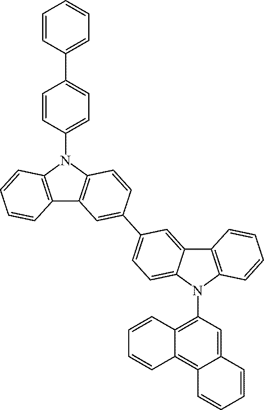 [SMILES: c1ccc(-c2ccc(-n3c4ccccc4c4cc(-c5ccc6c(c5)c5ccccc5n6-c5cc6ccccc6c6ccccc56)ccc43)cc2)cc1] 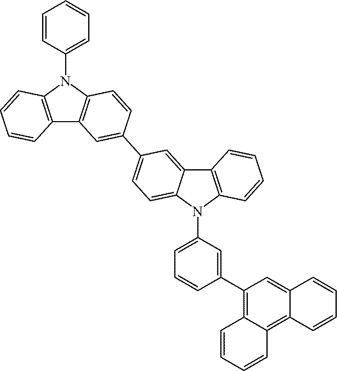 [SMILES: c1ccc(-n2c3ccccc3c3cc(-c4ccc5c(c4)c4ccccc4n5-c4cccc(-c5cc6ccccc6c6ccccc56)c4)ccc32)cc1] 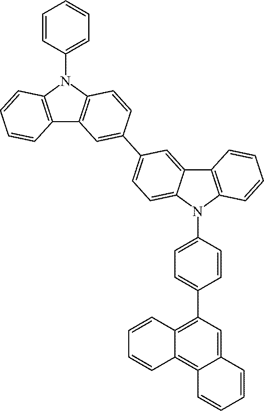 [SMILES: c1ccc(-n2c3ccccc3c3cc(-c4ccc5c(c4)c4ccccc4n5-c4ccc(-c5cc6ccccc6c6ccccc56)cc4)ccc32)cc1] 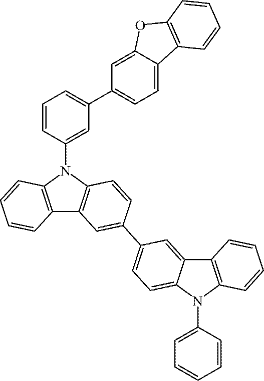 [SMILES: c1ccc(-n2c3ccccc3c3cc(-c4ccc5c(c4)c4ccccc4n5-c4cccc(-c5ccc6c(c5)oc5ccccc56)c4)ccc32)cc1] 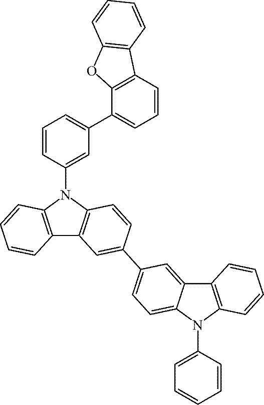 [SMILES: c1ccc(-n2c3ccccc3c3cc(-c4ccc5c(c4)c4ccccc4n5-c4cccc(-c5cccc6c5oc5ccccc56)c4)ccc32)cc1] 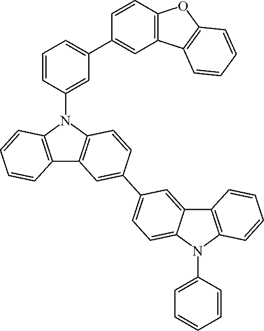 [SMILES: c1ccc(-n2c3ccccc3c3cc(-c4ccc5c(c4)c4ccccc4n5-c4cccc(-c5ccc6oc7ccccc7c6c5)c4)ccc32)cc1] 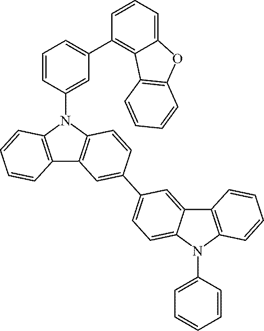 [SMILES: c1ccc(-n2c3ccccc3c3cc(-c4ccc5c(c4)c4ccccc4n5-c4cccc(-c5cccc6oc7ccccc7c56)c4)ccc32)cc1] 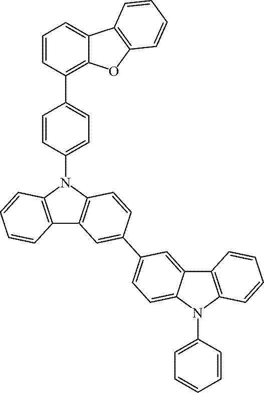 [SMILES: c1ccc(-n2c3ccccc3c3cc(-c4ccc5c(c4)c4ccccc4n5-c4ccc(-c5cccc6c5oc5ccccc56)cc4)ccc32)cc1] 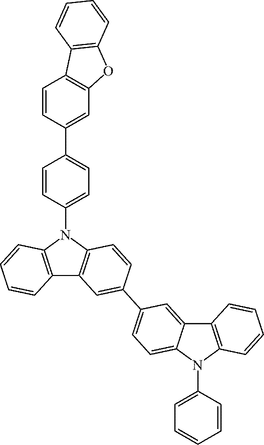 [SMILES: c1ccc(-n2c3ccccc3c3cc(-c4ccc5c(c4)c4ccccc4n5-c4ccc(-c5ccc6c(c5)oc5ccccc56)cc4)ccc32)cc1] 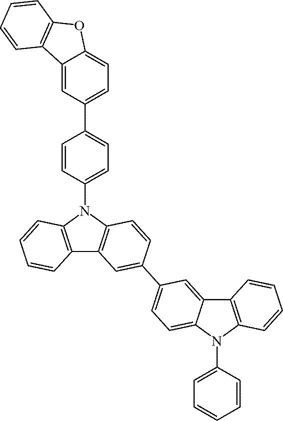 [SMILES: c1ccc(-n2c3ccccc3c3cc(-c4ccc5c(c4)c4ccccc4n5-c4ccc(-c5ccc6oc7ccccc7c6c5)cc4)ccc32)cc1] 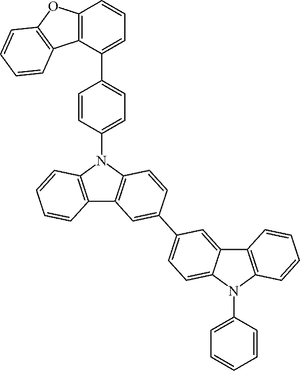 [SMILES: c1ccc(-n2c3ccccc3c3cc(-c4ccc5c(c4)c4ccccc4n5-c4ccc(-c5cccc6oc7ccccc7c56)cc4)ccc32)cc1] 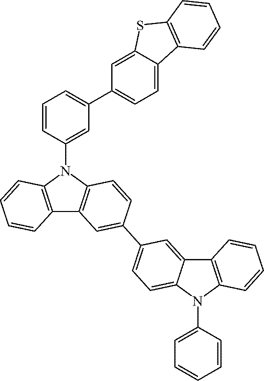 [SMILES: c1ccc(-n2c3ccccc3c3cc(-c4ccc5c(c4)c4ccccc4n5-c4cccc(-c5ccc6c(c5)sc5ccccc56)c4)ccc32)cc1] 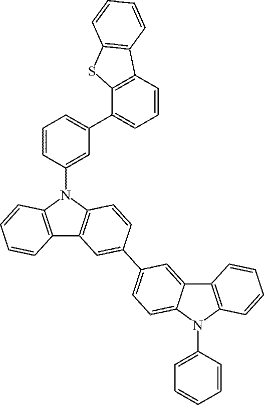 [SMILES: c1ccc(-n2c3ccccc3c3cc(-c4ccc5c(c4)c4ccccc4n5-c4cccc(-c5cccc6c5sc5ccccc56)c4)ccc32)cc1] 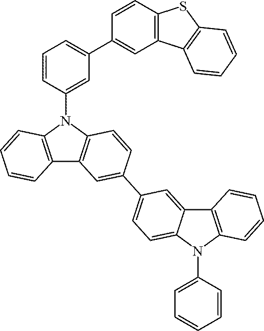 [SMILES: c1ccc(-n2c3ccccc3c3cc(-c4ccc5c(c4)c4ccccc4n5-c4cccc(-c5ccc6sc7ccccc7c6c5)c4)ccc32)cc1] 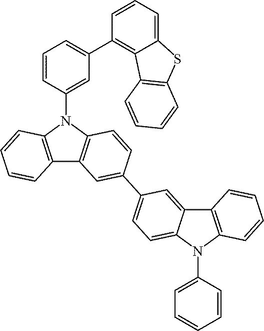 [SMILES: c1ccc(-n2c3ccccc3c3cc(-c4ccc5c(c4)c4ccccc4n5-c4cccc(-c5cccc6sc7ccccc7c56)c4)ccc32)cc1] 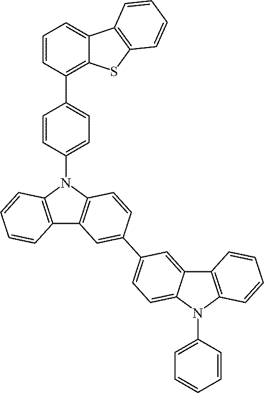 [SMILES: c1ccc(-n2c3ccccc3c3cc(-c4ccc5c(c4)c4ccccc4n5-c4ccc(-c5cccc6c5sc5ccccc56)cc4)ccc32)cc1] 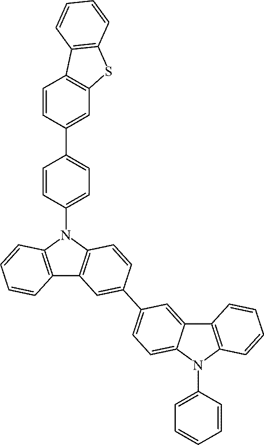 [SMILES: c1ccc(-n2c3ccccc3c3cc(-c4ccc5c(c4)c4ccccc4n5-c4ccc(-c5ccc6c(c5)sc5ccccc56)cc4)ccc32)cc1] 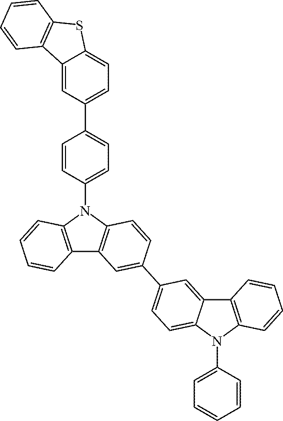 [SMILES: c1ccc(-n2c3ccccc3c3cc(-c4ccc5c(c4)c4ccccc4n5-c4ccc(-c5ccc6sc7ccccc7c6c5)cc4)ccc32)cc1] 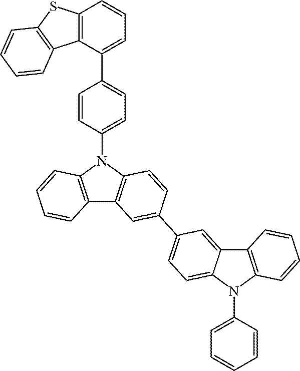 [SMILES: c1ccc(-n2c3ccccc3c3cc(-c4ccc5c(c4)c4ccccc4n5-c4ccc(-c5cccc6sc7ccccc7c56)cc4)ccc32)cc1] 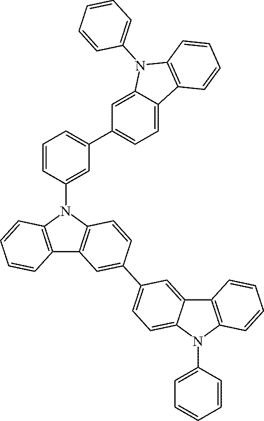 [SMILES: c1ccc(-n2c3ccccc3c3cc(-c4ccc5c(c4)c4ccccc4n5-c4cccc(-c5ccc6c7ccccc7n(-c7ccccc7)c6c5)c4)ccc32)cc1] 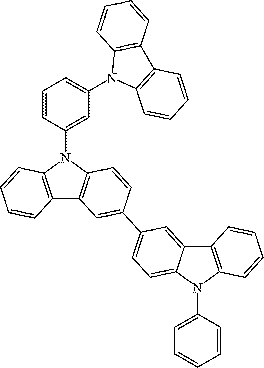 [SMILES: c1ccc(-n2c3ccccc3c3cc(-c4ccc5c(c4)c4ccccc4n5-c4cccc(-n5c6ccccc6c6ccccc65)c4)ccc32)cc1] 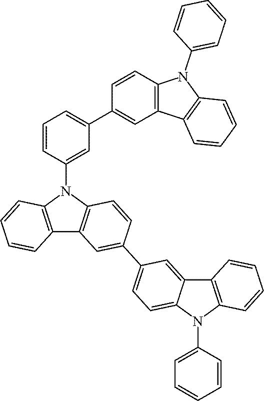 [SMILES: c1ccc(-n2c3ccccc3c3cc(-c4cccc(-n5c6ccccc6c6cc(-c7ccc8c(c7)c7ccccc7n8-c7ccccc7)ccc65)c4)ccc32)cc1] 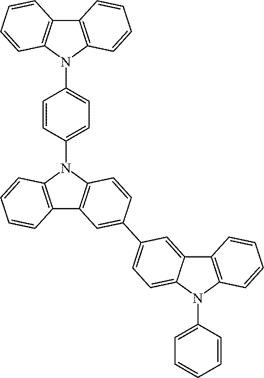 [SMILES: c1ccc(-n2c3ccccc3c3cc(-c4ccc5c(c4)c4ccccc4n5-c4ccc(-n5c6ccccc6c6ccccc65)cc4)ccc32)cc1] 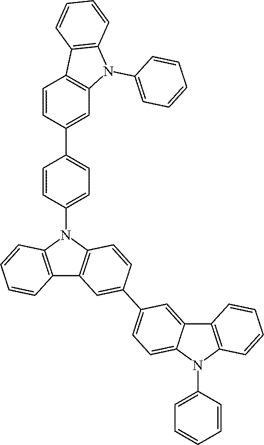 [SMILES: c1ccc(-n2c3ccccc3c3cc(-c4ccc5c(c4)c4ccccc4n5-c4ccc(-c5ccc6c7ccccc7n(-c7ccccc7)c6c5)cc4)ccc32)cc1] 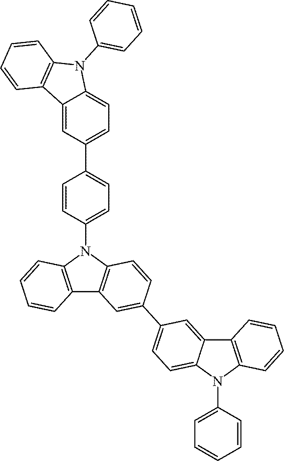 [SMILES: c1ccc(-n2c3ccccc3c3cc(-c4ccc(-n5c6ccccc6c6cc(-c7ccc8c(c7)c7ccccc7n8-c7ccccc7)ccc65)cc4)ccc32)cc1]
.

11. A light emitting device comprising:
a first electrode and a second electrode facing each other; and
a light emitting unit comprising a p-type charge generation layer, a hole transport layer, a green light emitting layer and an electron transport layer sequentially stacked,
wherein the green light emitting layer comprises a first material represented by the following Formula 1 and a phosphorescent dopant, and
the hole transport layer comprises a biscarbazole-based compound as a second material, 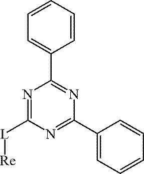
wherein Re includes at least one of a dibenzofuran group, a dibenzothiophene group, a triphenyl group, a triphenylene group, a carbazole group, a benzocarbazole group, an indenocarbazole group, a biscarbazole group, a fluorene group and a phenyl-carbazole group; and
L is a single bond or includes at least one of a phenyl group, a phenylene group, a biphenyl group, a biphenylene group, a dibenzofuran group, a dibenzofurylene group, a dibenzothiophene group and a dibenzothienylene group.

12. The light emitting device according to claim 11, wherein the second material is represented by Formula 2: 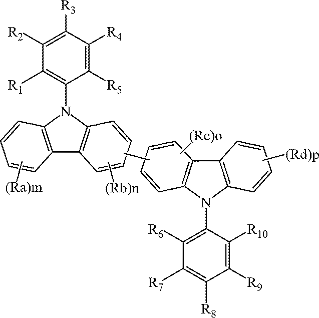
wherein Ra to Rd are each independently selected from hydrogen, deuterium, halogen, a substituted or unsubstituted C1-C6 alkyl group, a substituted or unsubstituted C3-C6 cycloalkyl group, a substituted or unsubstituted C6-C15 aryl group, a substituted or unsubstituted C5-C9 heteroaryl group, a carbazole group, a dibenzofuran group, a dibenzothiophene group, a trialkylsilyl group, and a triarylsilyl group;
m and p are each independently selected from integers from 0 to 4;
n and o are each independently selected from integers from 0 to 3; and
R₁ to R₁₀ are each independently selected from hydrogen, deuterium, halogen, a substituted or unsubstituted C1-C6 alkyl group, a substituted or unsubstituted C6-C18 aryl group, a carbazole group, a phenyl-carbazole group, a dibenzofuran group, and a dibenzothiophene group; or two or more of R₁ to R₁₀ together with the phenyl group that they are connected with may form a condensed aryl group.

13. A light emitting device comprising:
a first electrode and a second electrode facing each other; and
a red stack, a first blue stack, a green stack, and a second blue stack sequentially disposed between the first electrode and the second electrode,
wherein the green stack comprises a hole transport layer, a green light emitting layer, and an electron transport layer sequentially stacked,
wherein the green light emitting layer comprises a first material represented by the following Formula 1 and a phosphorescent dopant, and
the hole transport layer comprises a biscarbazole-based compound as a second material, 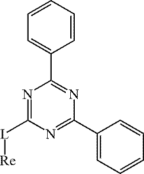
wherein Re includes at least one of a dibenzofuran group, a dibenzothiophene group, a triphenyl group, a triphenylene group, a carbazole group, a benzocarbazole group, an indenocarbazole group, a biscarbazole group, a fluorene group and a phenyl-carbazole group; and
L is a single bond or includes at least one of a phenyl group, a phenylene group, a biphenyl group, a biphenylene group, a dibenzofuran group, a dibenzofurylene group, a dibenzothiophene group and a dibenzothienylene group.

14. The light emitting device according to claim 13, wherein the second material is represented by Formula 2: 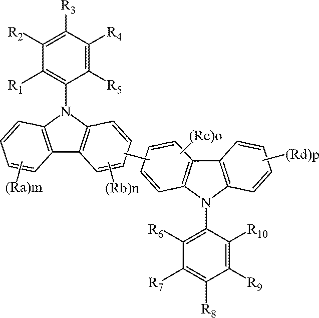
wherein Ra to Rd are each independently selected from hydrogen, deuterium, halogen, a substituted or unsubstituted C1-C6 alkyl group, a substituted or unsubstituted C3-C6 cycloalkyl group, a substituted or unsubstituted C6-C15 aryl group, a substituted or unsubstituted C5-C9 heteroaryl group, a carbazole group, a dibenzofuran group, a dibenzothiophene group, a trialkylsilyl group, and a triarylsilyl group;
m and p are each independently selected from integers from 0 to 4;
n and o are each independently selected from integers from 0 to 3; and
R₁ to R₁₀ are each independently selected from hydrogen, deuterium, halogen, a substituted or unsubstituted C1-C6 alkyl group, a substituted or unsubstituted C6-C18 aryl group, a carbazole group, a phenyl-carbazole group, a dibenzofuran group, and a dibenzothiophene group; or two or more of R₁ to R₁₀ together with the phenyl group that they are connected with may form a condensed aryl group.
